(19) United States
(12) Patent Application Publication
(10) Pub. No.: US 2024/0404840 A1
(43) Pub. Date: Dec. 5, 2024

(54) MOLDED DIRECT CONTACT INTERCONNECT SUBSTRATE AND METHODS OF MAKING SAME

(71) Applicant: Deca Technologies USA, Inc., Tempe, AZ (US)

(72) Inventors: Craig Bishop, Scottsdale, AZ (US); Paul R. Hoffman, San Diego, CA (US); Robin Davis, Vancouver, WA (US); Timothy L. Olson, Phoenix, AZ (US)

(21) Appl. No.: 18/801,313

(22) Filed: Aug. 12, 2024

Related U.S. Application Data
(63) Continuation-in-part of application No. 18/225,064, filed on Jul. 21, 2023, now Pat. No. 12,062,550.
Application No. 18/225,064 is a continuation-in-part of application No. 18/195,090, filed on May 9, 2023, now Pat. No. 11,973,051.
Application No. 18/225,064 is a continuation-in-part of application No. 17/957,683, filed on Sep. 30, 2022, now Pat. No. 11,749,534.
(60) Provisional application No. 63/391,694, filed on Jul. 22, 2022.
(60) Provisional application No. 63/347,516, filed on May 31, 2022.
(60) Provisional application No. 63/391,315, filed on Jul. 21, 2022.
(60) Provisional application No. 63/667,609, filed on Jul. 3, 2024.

(51) Int. Cl. H01L 21/48; B41M 5/00; B41M 5/26; G06K 7/10; H01L 25/00

(52) U.S. Cl. CPC H01L 21/4857; G06K 7/10366; H01L 25/50; B41M 5/0041; B41M 5/265

(57) ABSTRACT

The disclosure concerns method of making an interconnect substrate that may comprise providing a core. The core may comprise a composite core, which may comprise a PCB, a laminate core with build-up layers, or molded core. A first patterned frontside conductive layer may be formed over a front side of the core. A first frontside molded dielectric layer may be disposed over the front side of the core and over the first patterned frontside conductive layer. One or more other dielectric layers (such as polyimide) may be disposed before (and under) the first frontside molded dielectric layer. The core may be flipped such that a back side of the core is presented or configured for processing. A first patterned frontside conductive layer may be formed over the back side of the core.

### CROSS-REFERENCE TO RELATED APPLICATIONS

This disclosure is a continuation-in-part of U.S. Utility application Ser. No. 18/225,064 entitled “Molded Direct Contact Interconnect Substrate and Method of Making the Same,” which was filed on Jul. 21, 2023, which claims the benefit, including the filing date, of U.S. Provisional Patent No. 63/391,694, entitled “Molded Direct Contact Interconnect Substrate,” which was filed on Jul. 22, 2022, the entirety of the disclosures of which are hereby incorporated herein by this reference; and application Ser. No. 18/225,064 is also a continuation-in-part of U.S. Utility application Ser. No. 18/195,090 entitled “Molded Direct Contact Interconnect Structure Without Capture Pads and Method for the Same,” which was filed on May 9, 2023, which claims the benefit of U.S. Provisional Patent No. 63/347,516, entitled “Molded Direct Contact Interconnect Build-up Structure Without Capture Pads,” which was filed on May 31, 2022, the entirety of the disclosures of which are hereby incorporated herein by this reference; and application Ser. No. 18/225,064 is also is a continuation-in-part of U.S. Utility application Ser. No. 17/957,683 entitled “Quad Flat No-lead (QFN) Package Without Leadframe and Direct Contact Interconnect Build-up Structure and Method for Making the Same,” which was filed on Sep. 30, 2022, which claims the benefit of U.S. Provisional Patent No. 63/391,315, entitled “Quad Flat No-lead (QFN) Package Without Leadframe and Direct Contact Interconnect Build-up Structure Without Capture Pads and Methods for Making the Same,” which was filed on Jul. 21, 2022, the entirety of the disclosures of which are hereby incorporated herein by this reference; and this disclosure also claims the benefit of U.S. Provisional Patent No. 63/667,609, entitled “Molded Direct Contact Interconnect Substrate,” which was filed on Jul. 3, 2024 the entirety of the disclosures of which are hereby incorporated herein by this reference.

### TECHNICAL FIELD

This disclosure relates to electrical assemblies and more particularly to molded core substrates and build-up structures, such as for use with semiconductor structures, devices, and packages, and methods of making same.

### BACKGROUND

Semiconductor assemblies, devices, packages, substrates, and interposers are commonly found in modern electronic products. Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment, as well as in other fields and applications.

### SUMMARY

An opportunity exists for an improved method of making a molded core substrate. According to an aspect, the method of making a molded core substrate may comprise providing a substrate core having at least one tracking identifier disposed therein and comprising at least one embedded component. The substrate core may comprise one or more of: encapsulant, layers of glass fiber, a glass reinforced epoxy material such as FR4, CEM, plastic, polymer, mold compound such as epoxy or a thermoset material, a printed circuit board (PCB) with or without routing, a PCB core, metal, silicon, fiberboard, layers of paper laminated with epoxy or phenolic resin, carbon fiber, and composite. The embedded component may comprise one or more of: an active component, a chip, a die, a passive component, embedded capacitors, deep trench capacitors, inductors, bridge die, voltage regulators, RF components, optical components, opto-electronic components, conductive interconnects, and vertical interconnect blocks (VIB). A first patterned frontside conductive layer may be formed comprising at least one conductive trace, via, land, plane, line, and pad configured to be electrically coupled to the at least one embedded component over a front side of the substrate core. A first frontside layer of encapsulant or dielectric may be disposed over the front side of the substrate core, the at least one embedded component, and the first patterned frontside conductive layer. The substrate core may be flipped such that a back side of the substrate core is configured for processing. A first patterned backside conductive layer may be formed comprising at least one conductive trace, via, land, plane, line, and pad over the back side of the substrate core, the first patterned frontside conductive layer configured to be electrically coupled to the at least one embedded component. A first backside layer of encapsulant or dielectric may be disposed over the back side of the substrate core, over the at least one embedded component, and over the first patterned frontside conductive layer. The first backside layer of encapsulant may be planarized by grinding, chemical mechanical polishing (CMP), surface planarization, polishing, plasma etching, wet etching, or thinning by using a diamond-based cutter, to expose at least a portion of the first patterned backside conductive layer to form a first backside planar surface on the first backside layer of encapsulant. A second patterned backside conductive layer may be formed over the first backside planar surface, the second patterned backside conductive layer configured to be electrically coupled to the first patterned frontside conductive layer. A second backside layer of encapsulant may be disposed over the second patterned backside conductive layer and the first backside planar surface. The substrate core may be flipped such that the first patterned frontside layer of encapsulant is configured for processing. The first patterned frontside layer of encapsulant may be planarized to expose at least a portion of the first patterned frontside conductive layer to form a first frontside planar surface on the first frontside layer of encapsulant. A second patterned frontside conductive layer may be formed over the first frontside planar surface, the second patterned frontside conductive layer configured to be electrically coupled to the first patterned frontside conductive layer. A second frontside layer of encapsulant may be disposed over the second patterned frontside conductive layer and the first frontside planar surface. The substrate core may be flipped such that the second backside layer of encapsulant is configured for processing. The second backside layer of encapsulant may be planarized to expose at least a portion of the second patterned backside conductive layer to form a second backside planar surface on the second backside layer of encapsulant.

In various instances the substrate core may comprise a mold compound formed by a molding process. At least one of the first frontside layer of encapsulant, the second frontside layer of encapsulant, the first backside layer of encapsulant, and the second backside layer of encapsulant may comprise mold compounds that are formed by a molding process or comprise a build-up film applied by lamination. The tracking identifier may comprise a 2-dimensional (2D) code comprising a data matrix, a laser mark, a witness mark, an ink mark, an inductor, an antenna, an RFID component, an accelerometer, or a directional component. The method may further comprise providing the at least one tracking identifier as a first tracking identifier and a second tracking identifier; reading the first tracking identifier, wherein the first tracking identifier is a 2D code, laser mark, witness mark, or the ink mark; applying the second tracking identifier opposite the first tracking identifier; and removing the first tracking identifier. The method may further comprise reading the tracking identifier comprising the inductor, the antenna, the RFID component or the directional component. The encapsulant may comprise a mold compound, a composite material, such as epoxy resin with filler, epoxy acrylate with filler, polytetrafluoroethylene, build-up film, or low k dielectrics.

According to an aspect, the method of making a molded core substrate may comprise providing a core, wherein the core comprises a composite core or molded core. A first patterned frontside conductive layer may be formed over a front side of the core. A first frontside molded dielectric layer may be disposed over the front side of the core and over the first patterned frontside conductive layer. The core may be flipped such that a back side of the core is configured for processing. A first patterned frontside conductive layer may be formed over the back side of the core.

In various instances the method may comprise disposing a first backside dielectric layer over the back side of the composite core or molded core and over the first patterned frontside conductive layer; planarizing the first backside molded dielectric layer to expose at least a portion of the first patterned backside conductive layer to form a first backside planar surface on the first backside dielectric layer; forming a second patterned backside conductive layer over the first backside planar surface; disposing a second backside dielectric layer over the second patterned backside conductive layer and the first backside planar surface; flipping the composite core or molded core such that the first frontside dielectric layer is configured for processing; and planarizing the first frontside dielectric layer to expose at least a portion of the first patterned frontside conductive layer to form a first frontside planar surface on the first frontside dielectric layer. The method may further comprise forming additional frontside and backside conductive layers interleaved with additional frontside and backside dielectric layers to form up to 30 layers of conductive frontside layers and conductive backside layers, and up to 30 layers of frontside and backside dielectric layers; and counterbalancing stress and warpage by alternating the formation of the additional frontside and backside conductive layers and the additional frontside and backside dielectric layers. The at least one frontside conductive layer or at least one backside conductive layer may be formed with unit specific patterning. At least one of the composite core or molded core and first frontside or first backside dielectric layers may further comprise at least one tracking identifier comprising one or more of a 2-dimensional (2D) code, a laser mark, a witness mark, an ink mark, an inductor, an antenna, an RFID component, an accelerometer, or a directional component. The method may further comprise forming the composite core or molded core from at least one mold compound using a molding process, and forming at least one of the frontside and backside dielectric layers from an encapsulant or a laminated build-up film that performs well in a grinding operation. The method may further comprise forming the at least one tracking identifier as a first tracking identifier and a second tracking identifier; reading the first tracking identifier, wherein the first tracking identifier is a 2D code, laser mark, witness mark, or ink mark; applying a second tracking identifier opposite the first tracking identifier; and removing the first tracking identifier. The method may further comprise reading the tracking identifier comprising the inductor, the antenna, the RFID component or the directional component. The dielectric layer may comprise a mold compound, a composite material, such as epoxy resin with filler, epoxy acrylate with filler, polytetrafluoroethylene, a build-up film, a dielectric, low k dielectrics; and one or more other dielectric layers may comprise polyimide, may be disposed before, and under or in place of, the first frontside molded dielectric layer.

According to an aspect, the method of making a molded core substrate may comprise providing an unreinforced substrate core; forming at least one vertical interconnect through a thickness of the unreinforced substrate core, wherein the vertical interconnect comprises at least one of: a conductive vertical interconnect; a vertical interconnect block (VIB); a vertical conductive contact; a conductive stump; a vertical connecting element, and a via. A first patterned frontside conductive layer may be formed comprising at least one conductive trace, via, land, plane, line, and pad over a front side of the unreinforced substrate core. The first patterned frontside conductive layer may be coupled to the at least one vertical interconnect. A first frontside dielectric layer may be disposed over the front side of the unreinforced substrate core and over the first patterned frontside conductive layer. The unreinforced substrate core may be flipped such that a back side of the unreinforced substrate core is configured for processing. A first patterned backside conductive layer may be formed comprising at least one conductive trace, via, land, plane, line, and pad over the back side of the unreinforced substrate core. The first patterned frontside conductive layer may be coupled to the at least one vertical interconnect. A first backside dielectric layer may be disposed over the back side of the unreinforced substrate core and over the first patterned frontside conductive layer.

In various instances, the method of making a molded interconnect substrate of may further comprise a tracking identifier comprising a 2-dimensional (2D) code comprising a data matrix, a laser mark, a witness mark, an ink mark, an inductor, an antenna, an RFID component, or a directional component. The method may further comprise reading the tracking identifier, wherein the tracking identifier comprises the 2D code, the laser mark, the witness mark, or the ink mark; applying an additional tracking identifier opposite the tracking identifier; and removing the tracking identifier by planarizing. The method may further comprise reading the tracking identifier comprising the inductor, the antenna, the RFID component or the directional component.

The foregoing and other aspects, features, applications, and advantages will be apparent to those of ordinary skill in the art from the specification, drawings, and the claims. Unless specifically noted, it is intended that the words and phrases in the specification and the claims be given their plain, ordinary, and accustomed meaning to those of ordinary skill in the applicable arts. The inventors are fully aware that they can be their own lexicographer if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112(f). Moreover, even if the provisions of 35 U.S.C. § 112(f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

### BRIEF DESCRIPTION OF THE DRAWINGS

FIGS. 1A-1D illustrate various view of a molded substrate comprising components coupled thereto;

FIGS. 2A-2V illustrate various stages of a molded substrate being formed over a substrate or temporary carrier;

FIGS. 3A-3E illustrate various instances of vias, pads, and channels that may be incorporated within the molded substrate;

FIGS. 4A-4B illustrate instances of a molded substrate being formed on a conventional substrate or printed circuit board (PCB);

FIGS. 5A-5C illustrate instances of stacked layers of molded substrate and conventional substrate or PCB;

FIGS. 6A-6B illustrate close-up perspective views of molded build-up interconnect structures;

FIGS. 7A-7C are illustrations of components comprising electrical interconnects being singulated from a substrate or native wafer;

FIGS. 8A-8F illustrate non limiting exemplary embodiments of a substrate core as disclosed herein;

FIGS. 9A-9L illustrate various stages of forming a molded core substrate;

FIG. 10 illustrates an embodiment of a molded core assembly comprising the molded core substrate as disclosed herein, and

FIG. 11 shows an embodiment of a molded core assembly comprising a molded core substrate having conductive layers of varying thickness and vertical components disposed therein.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations.

### DESCRIPTION

This disclosure relates to molded core substrates and build-up structures (hereinafter “molded substrates”), such as for use with semiconductor structures, devices, and packages. In some instances, the molded core substrates may comprise one or more layers of molded substrates coupled with one or more conventional substrates. The molded substrate may include routing for semiconductor devices comprising different pitches, such as high density and ultra-high density as described more fully herein.

Molded core substrates (and method for making and using the same) may comprise or provide: (i) 2 micrometer line and space routing, (ii) removal of capture pads for vias between build-up layers, such as traces, and (iii) facilitate ultra-high-density connections.

Molded substrates also provide other advantages, including the formation of custom and use specific substrates, providing additional design options when being used with (or stacked on, in, or between) conventional substrates (such as circuit boards, printed circuit boards (PCBs) (whether single layer, double layer, multi-layer, high density interconnect (HDI), high frequency, formed with a core or without a core (coreless), with or without a mesh or glass weave reinforcement, rigid, flexible, rigid-flex, laminates, interposers, or any other substrate or support material).

Molded substrates further provide the additional advantages of conductive layers within the molded substrate being formed as more features within the molded substrate (e.g. more than copper or conductive posts), and further include: (i) vertical conductive interconnects, stump layers, power planes and power delivery systems, (ii) shielding for all or part of the molded substrate (such as when shielding is only for part of the molded substrate, the shielding may be targeted for high energy, high frequency, RFID, or for other application specific needs or operations), and (iii) patterned metal in any shape, including for inductors, antenna, markings for identification, such as part number, manufacture date or location, or other desired information.

Other features may also (but need not be) be formed within, adjacent, above, or below the molded substrate, including passive devices, integrated passive devices (IPDs), molded components, or other features included with the molded substrate. Molded components may comprise embedded devices, active devices, a semiconductor chip comprising an active layer, an IPD, or a passive device, silicon devices, integrated circuits, bridge chip, inductors, capacitors, and resistors, for power management, RF signal processing, clocking or devices for other functions. In some instances, the molded substrate will be formed without any molded components. Without molded components the molded substrate (or portions thereof may operate more as a conventional substrate or PCB and include conductive features for routing of electrical signals, the conductive features being formed as one or more studs, interconnects, routing layers, and redistribution layers.

At least some of the above advantages are available at least in part by using unit specific patterning (such as patterning (custom lithography) and build-up interconnect structures such as a frontside build-up interconnect structure, which is also known under the trademark “Adaptive Patterning,” referred to as “AP.” Unit specific patterning: (i) allows for the use high-speed chip attach for semiconductor chip and AP will ensure alignment for high density interconnects with the molded core build-up structures; and (ii) allows for automated optical inspection (AOI) and defect identification with the possibility for defect repair, which may include laser direct imaging (LDI) and plating for opens and may further include laser cut for shorts.

This disclosure, its aspects and implementations, are not limited to the specific package types, material types, or other system component examples, or methods disclosed herein. Many additional components, manufacturing and assembly procedures known in the art consistent with semiconductor wafer fabrication, manufacture and packaging are contemplated for use with particular implementations from this disclosure. Accordingly, for example, although particular implementations are disclosed, such implementations and implementing components may comprise any components, models, types, materials, versions, quantities, or the like as is known in the art for such systems and implementing components, consistent with the intended operation.

The word “exemplary,” “example” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

In the following description, reference is made to the accompanying drawings which form a part hereof, and which show by way of illustration possible implementations. It is to be understood that other implementations may be utilized, and structural, as well as procedural, changes may be made without departing from the scope of this document. As a matter of convenience, various components will be described using exemplary materials, sizes, shapes, dimensions, and the like. However, this document is not limited to the stated examples and other configurations are possible and within the teachings of the present disclosure. As will become apparent, changes may be made in the function, arrangement, or both of any of the elements described in the disclosed exemplary implementations without departing from the spirit and scope of this disclosure.

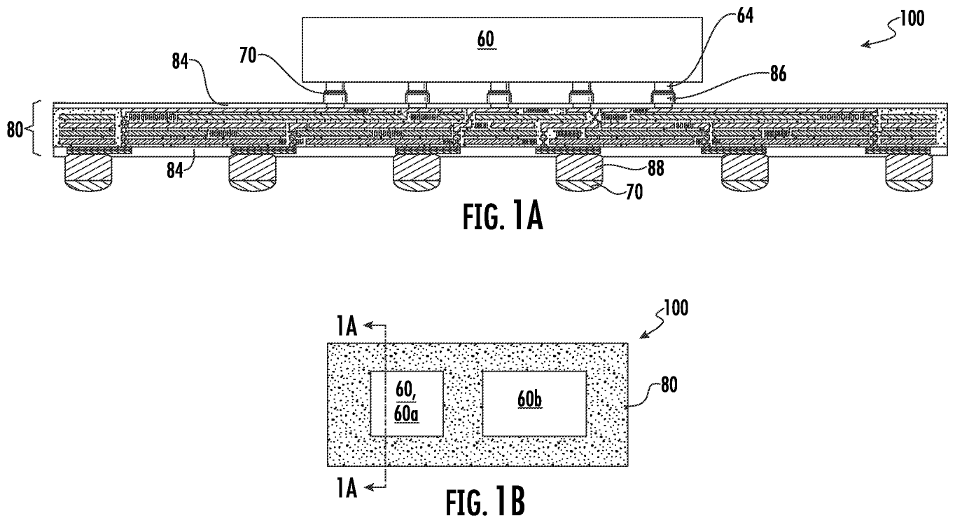

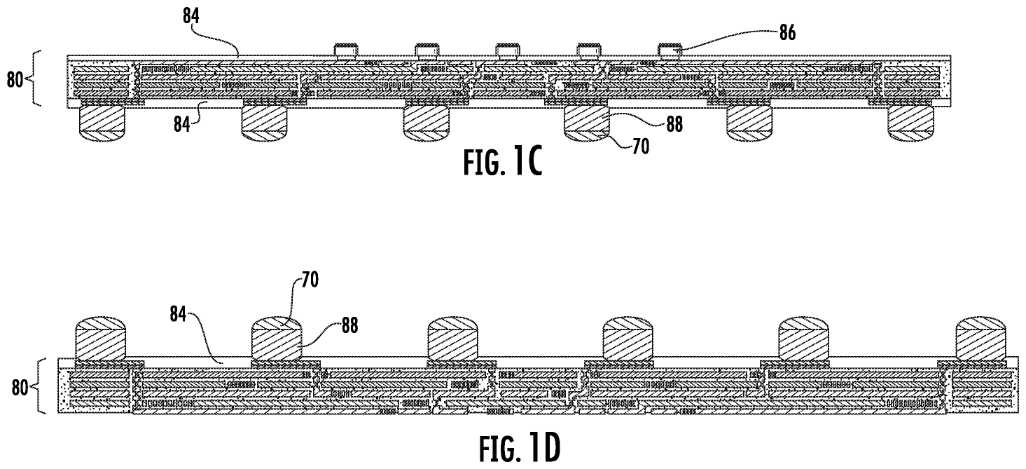

FIGS. 1A-1D illustrate a molded substrate 100 comprising one or more components 60 mounted or coupled thereto. In some embodiments, the component 60 may be a chip, semiconductor chip, die, semiconductor die, surface mount technology (SMT), or flip chip. Each component 60 may comprise a backside or back surface and an active layer opposite the backside. The active layer contains one or more circuits or discrete components of any kind implemented as active devices, or only conductive layers, and dielectric layers formed within or on the component 60 and electrically interconnected according to the electrical design and function of the component 60. For example, the circuit may include, without limitation, one or more transistors, diodes, and other circuit elements formed within active layer to implement analog circuits or digital circuits, such as DSP, ASIC, memory, or other signal processing circuits. The component 60 may also contain IPDs such as inductors, capacitors, and resistors, for RF signal processing. The component 60 may be a semiconductor chip formed on a native wafer in a wafer level process as one of many packages being formed simultaneously on a carrier. In other instances, the component 60 may be formed as part of a reconstituted wafer and may comprise multiple chips molded together. The component 60 may be an active chip, and in other instances may be formed without an active layer, for example as a bridge chip with only electrical routing and with copper studs of the semiconductor chip electrically connected or coupled with wiring, routing, or RDLs. The component 60 may also be only dummy silicon with no electrical function, but rather act as structural silicon and may or may not include copper studs. In some instances, both faces of the chip will be active. The component 60 may comprise conductive interconnects, studs, or bumps 64 that can be formed as one or more of bumps, thick pads, columns, pillars, posts, or conductive stumps that are disposed over the component 60. In some instances, the conductive studs may be coupled or connected to contact pads over the active layer of the semiconductor chip, when present.

In some instances, the temporary carrier 120 may be a metal carrier, a silicon carrier, a glass carrier, or a carrier made of other suitable material used for the molding or encapsulating process. The temporary or sacrificial carrier 120 may be removed such as by grinding or activating a release layer, after the encapsulant 142 over the carrier 120 provides sufficient structural support and the encapsulant 142 is no longer needed for support, wherein the encapsulant 142 may be any suitable material, such as mold compound, filled epoxy film such as filled epoxy film such as Ajinomoto Build-Up Film® (ABF), or other dielectric such as polyimide has been placed, cured, or both, such that the encapsulant 142 provides structural support and the temporary carrier 120 is no longer needed for processing. The carrier 120 may be of any suitable or desired size, such as panel of about 600 millimeters (mm) by 600 mm, or a panel having sides of less than 600 mm, such as 400 mm or 300 mm, as well as a wafer with circular or roughly circular footprint with a diameter or maximum width of about 400 mm or 300 mm. The carrier 120 may also be, or comprise one or more, strips with side lengths of less than or equal to about 300 mm, 200 mm, 150 mm, or 100 mm.

The component or semiconductor chip 60 may be placed adjacent one another, such as in a side-by-side arrangement, and subsequently coupled together. Multiple components 60 may also be processed together at a same time over the temporary carrier 120, which will be understood by a person of ordinary skill in the art (POSA), even when a close-up view of just portions of the assembly 100 are shown.

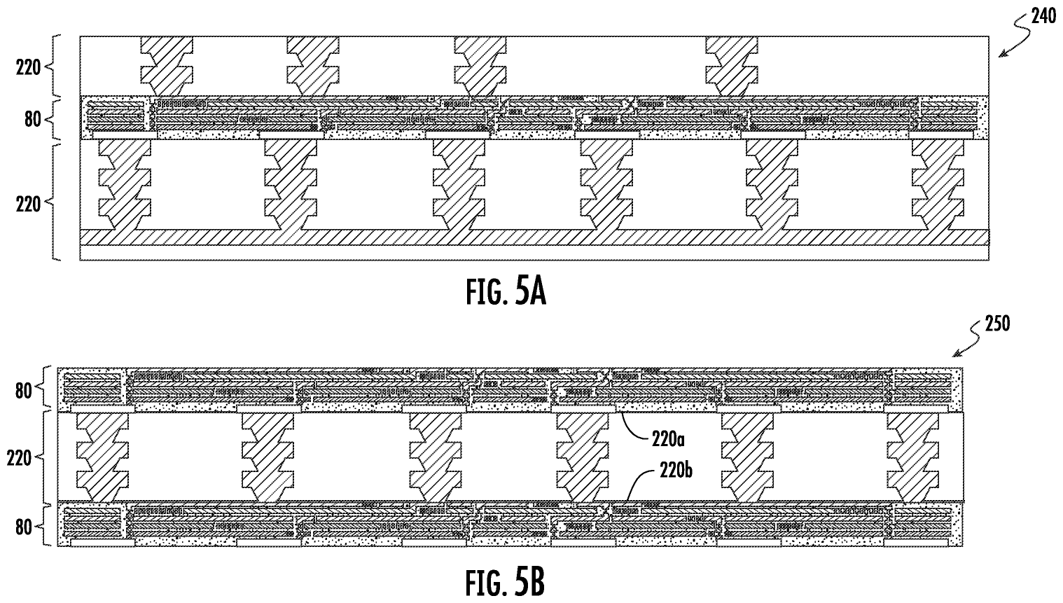

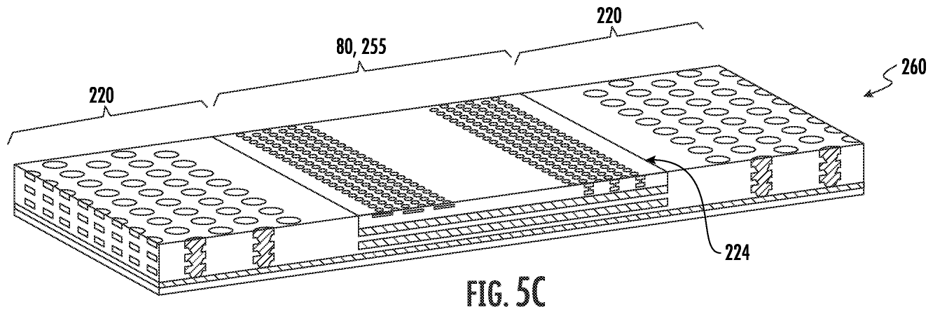

FIG. 1A illustrates an electronic assembly 100 comprising a component 60 mounted on a molded substrate or molded build-up interconnect structure 80. The component 60 comprises a conductive interconnect or bump 64 that contacts a conductive pad 86 of the build-up interconnect structure 80. On the opposite side of the molded substrate 80 from the component 60, the molded substrate 80 comprises an insulating, passivation or dielectric layer 84 and a conductive interconnect or bump 88 with solder 70 disposed at a distal end of the conductive interconnect 88. One or more components 60 may be mounted face-up or face-down to the molded substrate 80 as part of the electronic assembly 100. In some instances, the electronic assembly 100 will include the substrate 80 comprising both a PCB and molded layers being formed over the PCB, as shown and described, e.g., with respect to FIGS. 5A-5C.

FIG. 1B presents a top or plan view that is perpendicular to the view of FIG. 1A, wherein the electronic assembly 100 comprises more than one component 60 coupled to the build-up interconnect structure 80. More specifically, FIG. 1B shows a plan view of a first component 60a and a second component 60b attached to the build-up interconnect structure 80. FIG. 1B also includes a section line 1A, from which the cross-sectional profile view of FIG. 1A is taken.

FIG. 1C illustrates a cross-sectional profile view of a molded substrate 80 with conductive pads 86, and on an opposite side of the molded build-up interconnect structure 80, an insulating, passivation, or dielectric layer 84 and conductive interconnects 88 or bump with solder 70 at an end of the conductive interconnect 88 remote from build-up interconnect structure 80. Pads 86 at the surface of the molded substrate 80, in addition to being used for mounting components 60 thereto, may also be used as connectors or for being contacted as a socket or test probe. In some instances, the pads 80 may comprise a pad finish or solderable metal surface (SMS) or organic solderability preservative (OSP). Additionally, pads 86 may also be wirebondable (e.g., gold (Au), alladium (Pd), or silver (Ag). In some instances, pad finishes use or comprise a ‘hard’ finish, such as hard gold for connectors and test contact pads. In other instances, pad finishes use “soft” gold, such as are good for wirebonding. Components 60 may be mounted to, or onto, the substrate 80, using one or more of flip chip attach, die attach or direct attach, wire bonding, soldering, conductive paste, and conductive film.

FIG. 1D differs from FIG. 1C by the omission of conductive pads or bumps 86, which may be absent, or may be subsequently added. FIG. 1D illustrates a cross-sectional profile view of a molded substrate 80 with an insulating, passivation, or dielectric layer 84 and a conductive interconnect 88 or bump with solder 70 at an end of the conductive interconnect 88 remote from build-up interconnect structure 80.

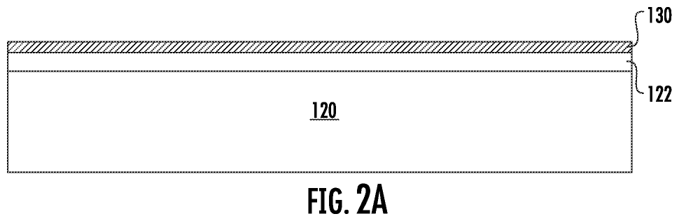

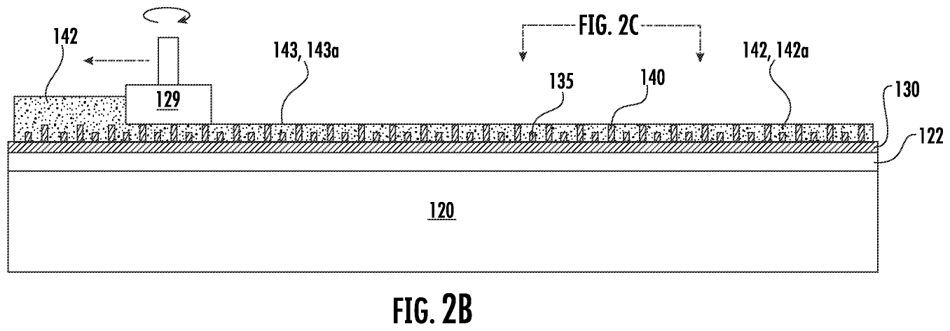

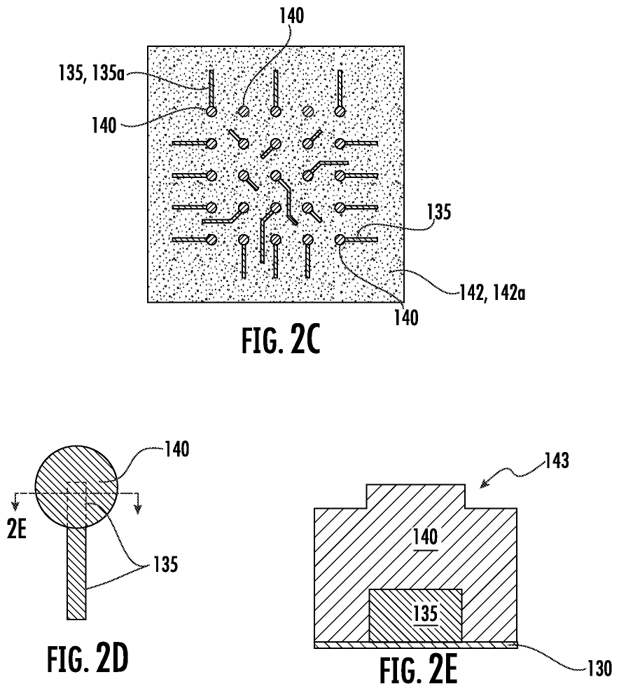

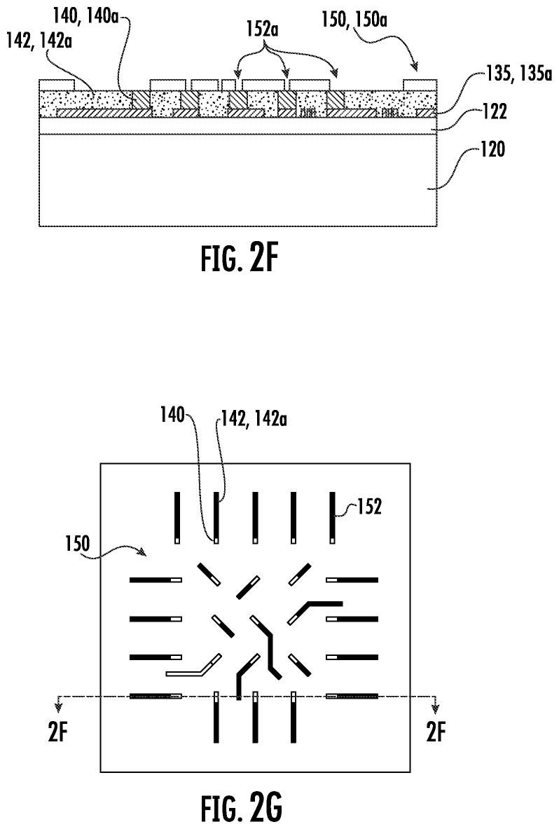

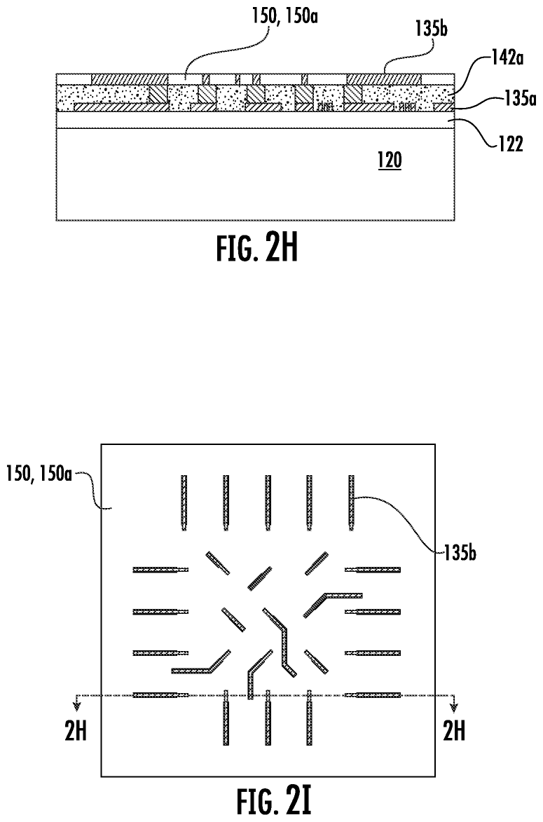

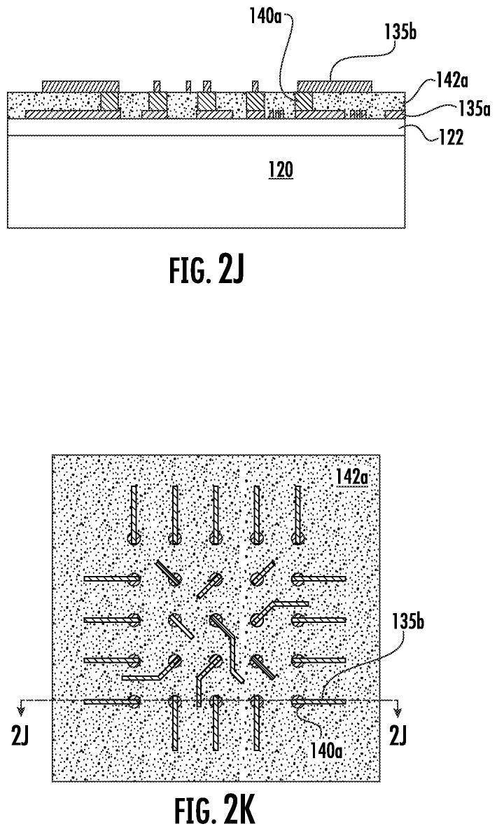

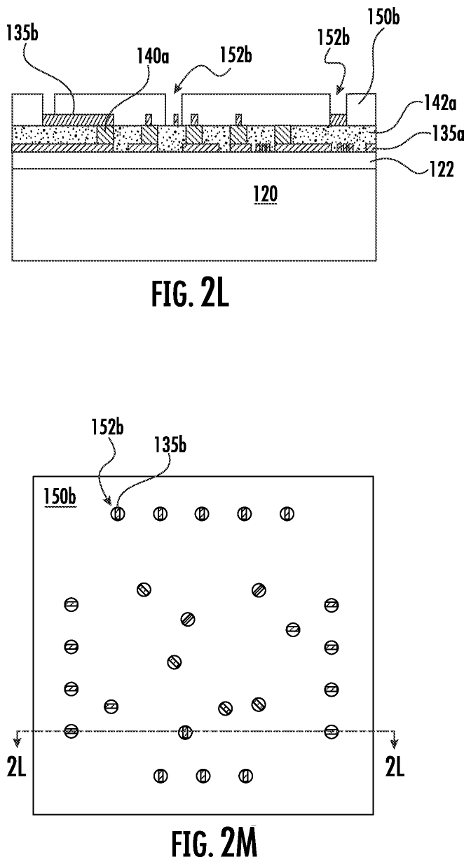

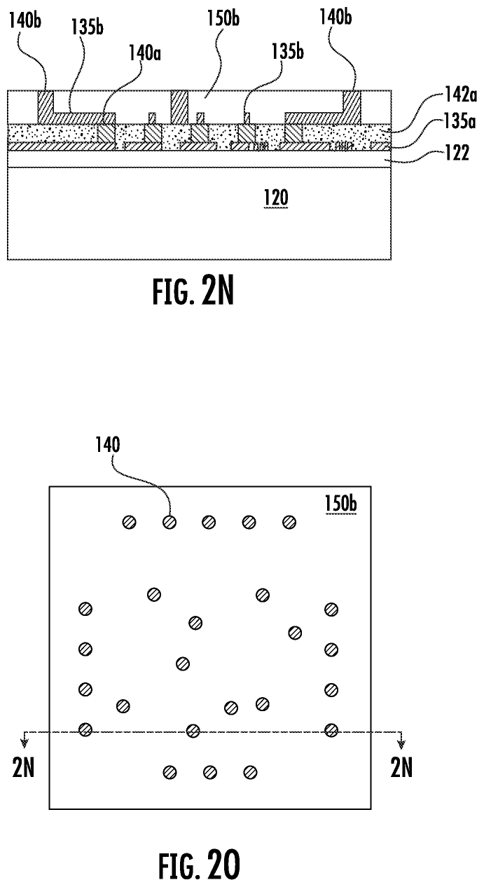

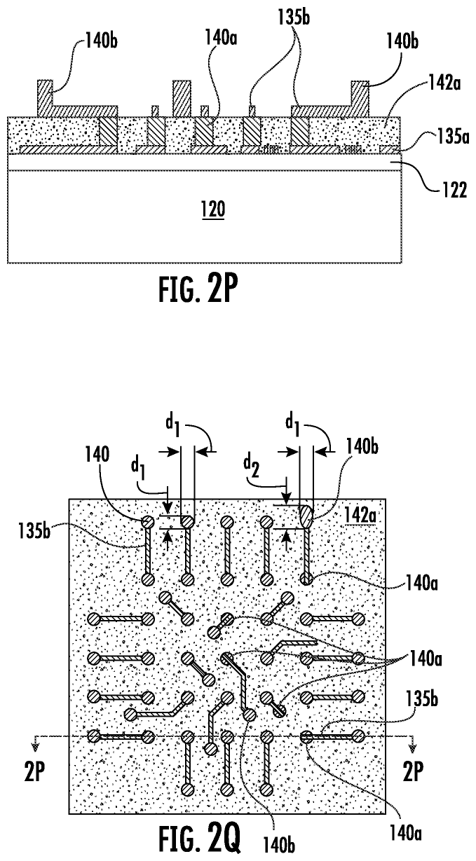

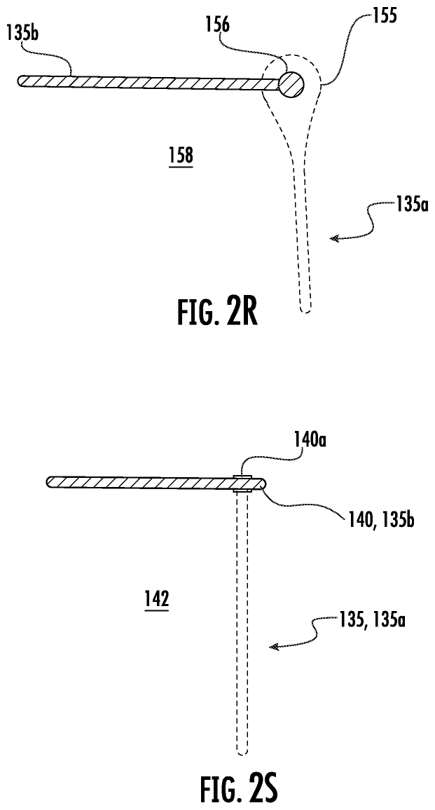

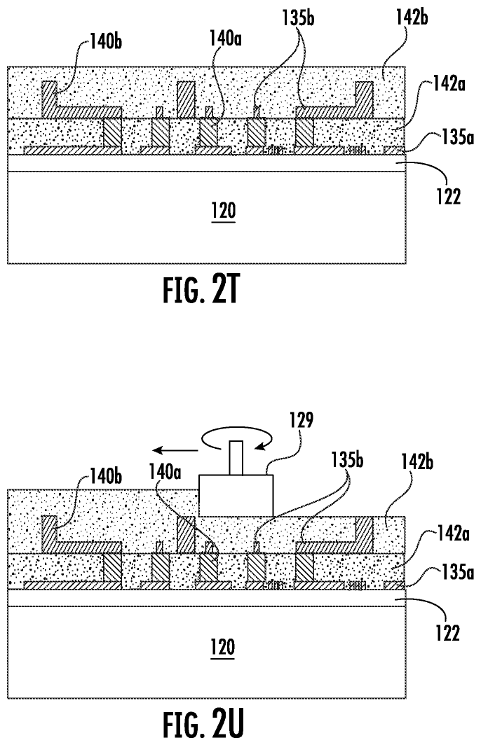

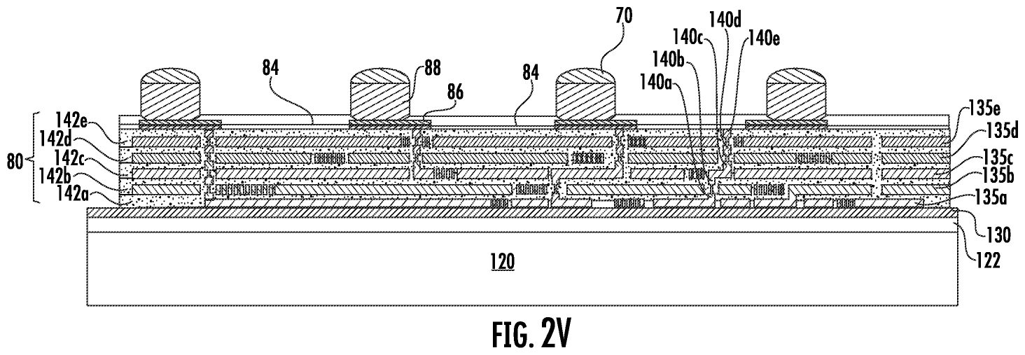

FIG. 2A illustrates a carrier or substrate 120 that that may be used for the formation of the molded substrate 80. In some instances, the carrier 120 may be a reusable carrier, a sacrificial carrier, or any suitable carrier that may be a metal carrier, a silicon carrier, a glass carrier, or a carrier made of mold compound, encapsulant, or other suitable material, which may further comprise a release layer. The carrier 120 may be used for the molding or encapsulating process, and then be removed after the encapsulant, such as mold compound, epoxy mold compound (EMC), a composite material, such as epoxy resin with filler, epoxy acrylate with filler, filled epoxy film such as ABF, or other dielectric such as polyimide has been placed, cured, or both, such that the encapsulant provides structural support and the temporary carrier is no longer needed for processing. In some instances, the carrier 120 may comprise a printed circuit board (PCB) that may be sacrificial, or alternatively some or all of which may remain and become a part of the molded substrate 80.

FIG. 2A further shows that in some instances an interface layer 122 may be disposed between the carrier 120 and the seed layer 130. The seed layer 130 may be used for the subsequent formation of conductive layers within the molded substrate 80, such as by electroplating.

The interface layer 122, when present, may provide temporary adhesion to the Molded build-up interconnect structure 80. The interface layer 122 may be one or more of a standard die attach liquid epoxy, other liquid adhesive, an adhesive film or tape, or a thermal release material, a thermal release tape, a UV release material, or a UV release tape that is disposed between the components and the intermediate carrier.

FIG. 2B illustrates a cross-sectional side view of forming a first conductive layer (trace, RDL, pad, plane, flag, or other structure) 135 and first vertical conductive contacts 140 over a seed layer 130. The first conductive layer 135 and first vertical conductive contacts 140 may be formed using PVD, CVD, electrolytic plating, electroless plating process, or other suitable metal deposition process. The seed layer 130 may utilize the same material and methods used to form the first conductive layer 135 and the first vertical conductive contacts 140. The first conductive layer 135 and first vertical conductive contacts 140 may be one or more layers of copper (Cu), aluminum (Al), tin (Sn), nickel (Ni), gold (Au), silver (Ag), titanium (Ti), Platinum (Pt), Tungsten (W) or other suitable electrically conductive material. The first conductive layers 135 and vertical conductive contacts 140 may be electrically conductive, thermally conductive, or both. The first conductive base may reside on an interface layer, adhesive, or tape 122 which resides on a carrier 120. For simplicity, the interface layer 122 and the carrier 120 are not shown on all of the figures that follow that show buildup of the conductive features.

Vertical conductive contacts 140 may be formed as conductive studs or conductive stumps which are conductive interconnect structures that may have generally vertical sides and be wider than tall. A conductive stud or stump 140 may differ from a pillar or post, each of which may have a height greater than its width. A conductive stud or stump 140 may comprise a cylindrical shape and may further be formed with a cross-sectional area that is circular, oval, octagonal, or as any polygonal or other shape and size. A conductive stud or stump 140 may be used for electrical interconnect, signal transmission, power, ground, or as a dummy thermal element that is not electrically coupled to an active electrical circuit but is instead thermally coupled to a heat source of an active device to dissipate the heat to another structure, such as to a die pad on a surface of the component 60. The generally vertical sides of a conductive studs or stumps 140 are different from the sides shape that exists for a solder ball or a compressed or outwardly deformed solder ball that has generally rounded sides. The generally vertical nature of a conductive studs or stumps 140 comes from being formed in a structure that has been previously developed or etched, such as within openings in a photoresist layer, which will also be generally vertical. Sides of the conductive stud or stump 140 may comprise imperfections or irregularities in shape that result from the developing or etching process, the photoresist material, or other materials and processes used. For example, developing or etching does not generally perfectly or uniformly remove the photoresist within the openings, and therefore forms imperfect, generally vertical openings for deposition of the conductive stud or stump. The term “generally vertical” as used herein includes perfectly vertical and imperfectly vertical sides or sides that are about or substantially vertical or at an angle typically greater than 45 degrees. A conductive stud or stump 140 is not a wire bond and is not solder.

FIG. 2C illustrates a top or planar view of an analogous structure to FIG. 2B, with the first conductive layer 135 formed over the carrier 120.

FIGS. 2B and 2C further illustrate the first conductive layer 135 can be formed as a trace or redistribution layer (RDL) comprising line and space of less than or equal to 2 μm for a pitch of less than or equal to 4 μm, or in other instances comprising line and space of less than or equal to 5 μm for a pitch of less than or equal to 10 μm.

The first vertical conductive contacts may also be formed at a same time as the conductive layer 135 (such as with a single-part or two-part plating processes). In the single plating process the following steps of features may be present: (i) forming a seed layer, (ii) forming and patterning a first photoresist or resist layer for the conductive layer 135 (or RDL), (iii) forming and patterning a second photoresist or resist layer for the first vertical conductive contacts 140 (or studs) or other conductive pattern, (iv) plating the conductive layer and the first vertical conductive contacts 140, (v) stripping or removing the photoresist, (vi) etch or remove the seed layer. Alternately, the process may be performed by (i) forming a seed layer, (ii) forming and patterning a first photoresist or resist layer for the conductive layer 135 (or RDL), (iii) plating the conductive layer 135, (iv) forming and patterning a second photoresist or resist layer for the first vertical conductive contacts 140 (or studs) or other conductive pattern, (vi) plating the first vertical conductive contacts 140, (vi) stripping or removing the photoresist, and (vi) etching or removing the seed layer. Additional alternate flows are possible to achieve the desired plated structure.

FIG. 2B illustrates that after formation of the conductive layer 135 and the first vertical conductive contacts 140, an encapsulant 142 or a first layer of encapsulant 142a, may be formed over the carrier 120, and over and around the conductive layer 135 and over and around the first vertical conductive contacts 140.

The encapsulant 142 may comprise a polymer composite material, such as epoxy resin with filler commonly referred to as epoxy molding compound or EMC, epoxy acrylate with filler, ABF (Ajinomoto Build-up Film®), or other polymer with proper filler. The encapsulant 142 may also comprise a flowable or non-flowable encapsulant or mold compound. For example, the encapsulant 142 may comprise an EMC which is a very flowable but has less filler. In other instances, encapsulant 142 with more filler could be used, which would make the encapsulant less flowable.

In certain embodiments, the planar surface 143 of the encapsulant layer 142a (or more specifically, the first planar surface 143a of the first encapsulant layer 142a) comprises a roughness less than 500 nanometers (nm) over a characteristic measurement distance. In some embodiments, after a sufficient number of layers of encapsulant 142 have been formed and the molded substrate 80 reaches a desired thickness and strength, the large carrier 120 may be removed. In some instances, the carrier 120 is removed after the molded substrate 80 is complete.

After disposing (and optionally curing) the encapsulant 142, the encapsulant layer 142 can undergo a grinding or chemical mechanical polishing (CMP) process with grinder 129. This is true of the first encapsulant 142a and any subsequent number of additional layers of encapsulant 142n or 142n₊₁. The grinding, or front grind, to remove a portion of the encapsulant 142 may form a substantially planar surface 143, or first planar surface 143a, over the first encapsulant layer 142a and the first conductive layer 125a. The substantially first planar surface 143a may comprise ends or exposed ends of the first vertical conductive contacts 140a and a planar surface of the first encapsulant layer 142a. The planarizing or grinding of the encapsulant produces a flatness of within a range of about 5-5000 nanometers (nm) or 100-500 nm across the planarized surface. The planar surface of the first encapsulant layer may comprise a roughness less than 500 nm over a characteristic measurement distance. The characteristic measurement distance is defined by the ISO 4288 standard, an entirety of which is hereby incorporated by reference. The characteristic measurement distance may also be a distance great enough to characterize the roughness, such as to a generally accepted level of certainty, and in some instances could be a distance of three times the distance of the roughness. While conventional encapsulant grinding might be done with less flatness, greater accuracy and precision can be obtained by using integrated sensors such as laser, acoustic, or other non-contact methods to control the grinding resulting in better flatness.

The first vertical conductive contacts 140a exposed at the first planar surface 142a may undergo an etching process with the rest of the planar surface 143a to remove metallic or copper residue that results from the grinding process. As a result, the first vertical conductive contacts 140a may be recessed with respect to the planar surface at a distance of, or about, 1-1,000 nm. As used herein, “about” or “substantially” means a percent difference less than or equal to 50% difference, 40% difference, 30% difference, 20% difference, 10% difference, or from 1% to 5% difference.

FIG. 2D illustrates a plan view of a topography of an upper surface of a vertical conductive contact 140 (e.g., first vertical contact 140a) that may result from a plating process where the vertical conductive contact 140 is plated over the conductive layer or trace 135, e.g., first conductive layer or trace 135a. FIG. 2E presents a cross-sectional side view 143 of FIG. 2D, including first vertical conductive contacts 140a and the first conductive layer 135a over the seed layer 130. As illustrated, the upper surface of the vertical conductive contact may be roughly the same as that of the conductive layer or trace over which it is plated. The non-planar topography of the upper portion of the vertical conductive contacts may be planarized in a subsequent grinding step.

In a single plate method (where the conductive layer 135 and the vertical contacts 140 are formed at a same time or in a same process) as well as in a dual-plate method or process (where the conductive layer 135 and the vertical contacts 140 are formed at a same time or in a same process), the following steps or features may be present. (i) A conductive seed layer may be formed, wherein the same seed is used in the plating processes for both the conductive layer 135 and the conductive contacts 140. Note that the seed layer may be the same or similar to the seed layer 130 shown in FIG. 2B. However, for simplicity of illustration, the seed layer 130 is omitted from subsequent illustration, as are subsequent seed layers that may be used for any number of conductive layers 135 (such as conductive layers 135a-135e, or 135n₊₁, and vertical conductive contacts 140a-140e, or 140n₊₁). For ease of reference, subsequent layers of a same or similar feature or material may be denoted by using the same reference number, followed by a letter or subscript (e.g., a-e, n₊₁). (ii) A first resist or photo resist layer 150, 150a with openings 152, 152a may be formed that may be used for the formation of conductive layer or RDL 135b, as illustrated in FIGS. 2F and 2G. (iii) The conductive layer 135b may be plated using the conductive layer and the first resist layer 150a, as illustrated in FIGS. 2H and 21. Note that a resist layer 150 (not shown in FIG. 2B), may also be used in the formation of the first conductive layer 135a, which is shown in FIG. 2B.

The process may further comprise (iv) striping the first resist 150a, as illustrated in FIGS. 2J and 2K. (v) The second resist or photo resist layer 150b with openings 152b may be formed and patterned for the second vertical conductive contacts 140b, as illustrated in FIGS. 2L and 2M. (vi) The second vertical conductive contacts 140b may be formed or plated, as illustrated in FIGS. 2N and 2O. As illustrated in FIGS. 2P and 2Q, (vii) the second resist 150b may be removed or stripped, and (viii) the seed layer may also be removed or etched. The vertical conductive contacts 140, including the second vertical conductive contacts 140b, may be formed with a minimum diameter less than or equal to about 12 μm or 5 μm and at a minimum pitch of less than or equal to about 25 μm or 10 μm. The second conductive layer 135b may comprise a redistribution layer (RDL) (or other feature without redistribution) with a line and space width of 2 μm or smaller.

FIGS. 2R and 2S illustrate a difference between an aspect of the instant disclosure (FIG. 2S) versus conventional structures (FIG. 2R). FIG. 2R illustrates how in conventional structures, large contact pads 155 are used to allow for significant tolerance in making contacts between vertically separated or vertically offset layers. A first or lower layer comprising conductive layer or conductive trace 135a and contact pads 155 (shown in dashed lines) is coupled with a second or higher layer comprising conductive layer or conductive trace 135b. Lower conductive trace 135 is coupled with higher conductive trace 135b through contact pad 155 and vertical connecting element or via 156. To accommodate the size and footprint of contact pad 155, additional spacing and an increased pitch are needed. On the other hand, FIG. 2S. illustrates the smaller footprint needed for conductive stump 140, which can be formed without the larger capture pad 155 using unit specific patterning or Adaptive Patterning™ for direct alignment with trace 135a. Unit specific patterning may use scanning and software to make adjustments that avoid the need for large conventional contact pads 155. In some embodiments, design software may adjust an x-y position or rotation of the patterned feature. The design software may create the unit-specific pattern design by selecting from a discrete number of design options or dynamically generating a new or custom unit-specific pattern. As a result, use of vertical conductive contacts or conductive stumps 140 as part of a molded substrate 80 (FIG. 2S) provides an added benefit of tighter or smaller spacing and pitch among conductive layers and features 135 with respect to conventional structures using contact pads 155 (FIG. 2R).

Additionally, FIG. 2R illustrates an instance in which a deformable insulting or passivating layer 158 is used in construction of conventional devices. The deformable insulating layer 158 is disposed around, and supports, both the conductive layers 135 and the vertical connecting elements or vias 156. Thereby the deformable insulating layer 158 assists in making a structure that facilitates connections between conductive layers 135 by using the contact pads 155 and the vertical connecting elements or vias 156. In conventional structures, like that shown in FIG. 2R, the deformable insulting or passivating layer 158 may be a polymer or polyimide that typically (but not always) does not support grinding. Grinding of the conventional insulting or passivating layer 158 can gum-up a grinder, not be cleanly removed so that a smooth surface is not produced, and otherwise be problematic for grinding and removal process, which are therefor avoided. In contrast, FIG. 2S shows a smaller conductive stump or vertical conductive contact 140 can be ground with the encapsulant 142 in a grinding process.

In FIG. 2S, the first vertical conductive contacts 140 cross-sectional area, as seen in top or plan view, that may be circular, square, oval, octagonal, or any other polygonal or desirable shape. The diameter—or greatest width—of the cross-sectional area of first (or any subsequent) vertical conductive contacts 140 (regardless of whether the cross-sectional area is circular or not) may be less than or equal to 8 μm. The first vertical conductive contacts may be at a pitch of less than or equal to 20 μm.

FIG. 2T illustrates disposing a second encapsulant layer 142b around the second conductive layer 135b, second vertical conductive contacts 140b, and over the first encapsulant layer 142a. The second encapsulant layer 142b may be similar, identical, or different than the first encapsulant layer. In any event, the second encapsulant layer 142 will support grinding of the encapsulant and second vertical conductive contacts or stumps 140b to form a second planar surface 143b, as shown in FIG. 2U.

FIG. 2V, continuing from FIG. 2U, illustrates a zoomed out cross-sectional profile view of the final structure or assembly 100 comprising a molded substrate 80, portions of which having been shown in the preceding FIGS. In FIG. 2V, the molded substrate 80 is positioned on seed layer 130 (not shown) that resides on an interface layer 122 that resides on a carrier 120. Continuing build-up pattern discussed with respect to the earlier figures, additional build-up layers of the molded substrate 80 can be added to the structure shown in FIG. 2U. The additional build-up layers may include: (i) conductive layers 135, such as conductive layers 135c-135e, (ii) additional vertical conductive contacts or stumps, such as vertical conductive contacts or stumps 140c-140e, and (iii) additional encapsulant layers, such as encapsulant layers 142c-142e. While 5 layers of conductive layers 135, vertical conductive contacts or stumps 140, and encapsulant 142 are shown in FIG. 2V, any number of desired layers of the materials may be used, including up to 6, 12, 18, 24 or more layers of conductive layers and vertical conductive contacts, or to any desirable number of layers. Planarizing may occur after each layer of encapsulant is formed or disposed.

FIG. 2V further illustrates forming: (iv) an insulating, passivation, or dielectric layer 84, and (v) a conductive pad 86 and a conductive contact 88 over (or as part of) the molded substrate 80. The molded substrate 80 is configured to be electrically coupled to other substrates, PCBs, assemblies, devices, chips, or other structures, through one or more of the conductive interconnects 88 and conductive pads 86, as shown, e.g. in FIG. 1A. The conductive interconnects 88 may comprise one or more of input-output (IO) electrical contacts, power or ground electrical contacts, a bump, a solder ball, a solder bump, a BGA, copper pillars, and copper pillars with solder, conductive polymer bumps, and nickel bumps to couple with devices outside the package. In other cases, there may be LGA pads or land pads provided to couple with devices outside the package.

By forming molded core build-up structures 80 with encapsulant 42, rather than deformable insulting or passivating layer 158, such as polymers or polyimide, as described herein, significant cost savings may be achieved. A cost of conventional packaging of a semiconductor chip may have roughly half of its cost associated with, or driven by, roughly 10 materials. The most expensive material can be polyimide, accounting for 10-20% of total package cost. The encapsulant 42, such as is used in place of the polyimide for the molded core build-up structures 80 is much less expensive than the polyimide, accounting for roughly 1-2% of total package cost. Thus, the molded core build-up structures 80 with encapsulant 42 may be roughly 5× to 10× cheaper, or one-fifth to one-tenth the cost, for using encapsulant 42 rather than polyimide.

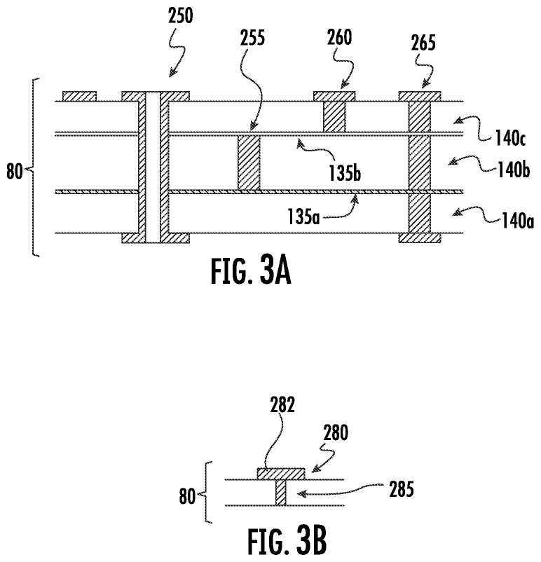

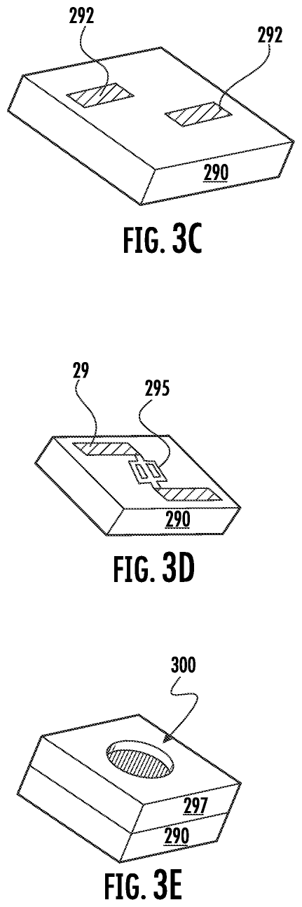

FIG. 3A illustrates examples of various via types that may be used in the molded substrates 80 described herein. In some embodiments, a through hole via 250 can extend through the entire substrate 80. Through hole vias 250 can be used for electrical connection or for mechanical purposes. Substrates 80 can also comprise buried vias 255. Buried vias 255 are positioned between conductive layers 275 in the interior of the substrate 80 and do not extend to the exterior, or are not exposed at outer surfaces of the substrate 80. Other vias may be blind vias 260. Blind vias 260 extend to one exterior surface but stops at some interior position and do not extend to the opposite surface. Yet other vias may be stacked vias 265. Such vias are positioned to be aligned with another via.

Another via concept, via in pad 280, is illustrated in FIG. 3B. Traditionally vias were kept outside of the bond pads because they can make the pad non-planer and bonding or reliability could be negatively affected. Via in pad 280 is an arrangement in which the via 285 is positioned under the pad 282 to form a via in pad 280, which as a combined structure, can alleviate the problem of non-planarity and reductions in bonding quality.

In certain embodiments, a flexible circuit can be attached to a rigid substrate, in which either all or part of the rigid substrate, the flexible substrate, or both, comprise a molded substrate 80. In some embodiments, desired components can be disposed within the substrate 80, such as by being attached or placed in a desired position, and then molded in place. The components may also be coupled or attached before being molded, such as by solder, pins, adhesive, mechanical fasteners, or in any other suitable fashion.

Some substrates my include materials specific for high resistance (to form resistors, for example) or materials with specific electromagnetic or magnetic properties embedded in the molded layers. Such layers may be applied physically (by screen printing, for example) or other deposition (CVD or sputtering, for example).

Yet other aspects include microfluidic devices 290 comprising molded-in wells or fluid channels 300 for applications such as biological assays. As illustrated in FIGS. 3C-3E, a molded-in well 300 can be disposed over, coupled with, or in communication with, an applied sensor 295 or other sensing material which contacts one or more traces 292. In some embodiments, a protective cover screen 297 may be placed over the sensor 295, which is coupled with traces 292 and well or channels 300.

High resistance additive traces can be added to some substrates to create a heater. Such heaters can be useful applications that require higher temperatures (such as some biological applications).

In some embodiments, trenches can be made in certain areas or desired locations and then filled with optically transparent or tuned material to create optical waveguides for opto-electrical applications. Other trenches can be placed in certain areas of the substrate to isolate some areas from other areas for uses such as thermal isolation.

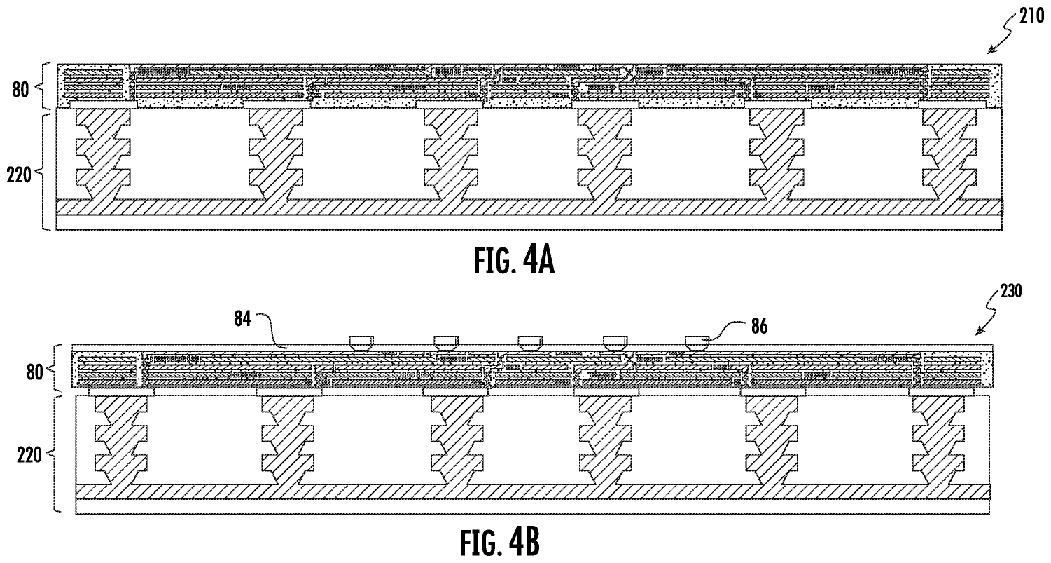

FIG. 4A illustrates a cross-sectional profile view of how a composite substrate 210 may be formed with a molded substrate portion 80 being formed on or over another conventional substrate 220. The conventional substrate 220 may be a PCB or other laminate material that may or may not comprise polyimide. In some instances, the conventional substrate 220 will remain (permanently) attached for structural support and additional connectivity. FIG. 4B, continuing from FIG. 4A, shows composite substrate 230 with an additional feature of first conductive pads or bumps 86 formed or disposed over the insulating, passivation, or dielectric layer 84, opposite the carrier or PCB 220. In some instances, as few as one layer of mold and grind may be used to form the molded substrate 80 over the conventional substrate or PCB 220 to expose a pad on the PCB, the pad being flush with the encapsulant 142 of the molded substrate 80. One or more components 60 may then be mounted (flip chip, face down, face up, or in any suitable way) to the composite substrate 210 or 230, as shown e.g., in FIG. 1A. The molded substrate 80 over the conventional substrate 220 may also be used to reduce a pitch of the routing or pads on the conventional substrate 220 to match a pitch or fan out pitch of the component 60. In some instances, arrangements of the molded substrate 80 or 220, or composite substrate 210 or 230, may be used to form a package on package (POP) structure. As a non-limiting example, the POP structure may include a first component 60 disposed face-up in the molded substrate 80, with a second component 60 flip-chip mounted over the first component 60. Any other desired POP arrangement may also be created using one or more components 60 and one or more molded substrate 80, 220 or one or more composite substrate 210, 230, 240, or 250.

FIGS. 5A and 5B illustrate examples of the molded substrate 80 being formed as part of a combination substrate 240, 250 comprising a stack or sandwich 240, 250. The combination substrate 240, 250 may comprise two or more layers of molded substrate 80 interleaved with one or more layers of PCB or conventional substrate 200. Alternatively, the combination substrate 240, 250 may comprise two or more layers of PCB or conventional substrate 220 interleaved with one or more layers of molded substrate 80.

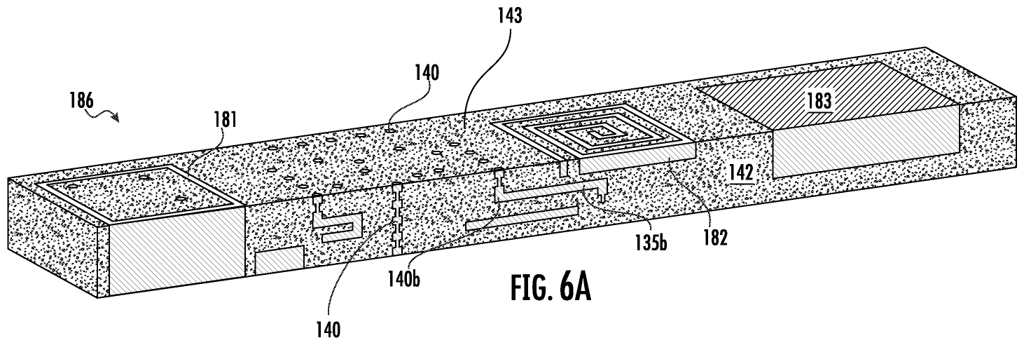

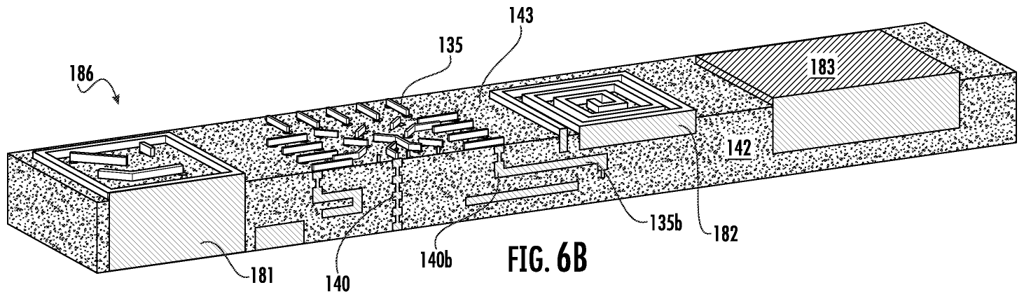

FIG. 5A illustrates a cross-sectional profile view of an aspect or embodiment of a combination molded substrate, PCB stack, or sandwich 240 in which the molded substrate 80 is sandwiched between two conventional substrates 220, such as PCBs as part of mechanically robust design that provides structural support for applications that need strong mechanical connections, such as passing drop tests, for military applications, and other similar situations. The composite or combination molded substrate 240 may be formed by forming a molded substrate 80 over a first conventional substrate 220 (similar to the process shown in FIGS. 2A-2V, after which a second conventional substrate 220 is mounted to or built up on the molded substrate 80. In various aspects, including those shown in FIGS. 5A and 5B, a consistent metal thickness may be present within the molded substrate 80 to provide improved performance and reliability. Additionally, the molded substrate 80 may provide finer pitch routing and higher density routing than would otherwise be included within a PCB. Other additional features, such as those presented in FIGS. 6A and 6B may also be present.

FIG. 5B illustrates a cross-sectional profile view of another aspect or embodiment of a combination molded substrate, PCB stack, or sandwich 250. The combination molded substrate 250 of FIG. 5B is the inverse of the combination molded substrate 240 of FIG. 5A. The combination molded substrate 250 of FIG. 5B includes two molded substrates 80 (upper and lower) formed on opposing first surface 220a and second surface 220b of conventional substrate 220, such as a PCB.

FIG. 5C illustrates a perspective view of a combination molded substrate 260 that incorporates a molded substrate 80 within an opening or window 224 formed within the conventional substrate 220, such as a PCB, so as to provide an island or region 255 of high-density interconnects within the substrate or PCB 220. In some instances, the window or opening 224 may go partially but not completely through the conventional substrate 220. In other instances, the window or opening 224 may go (or extend) completely through the conventional substrate 220. Any desirable arrangement of intermixing, filling stacking, or otherwise arranging molded substrates 80 and conventional substrates 220 may also be formed.

FIGS. 6A and 6B illustrate close-up perspective views of molded build-up interconnect structure 186 with the mold compound 142 contacting, disposed around, and supporting a number of features or elements. FIGS. 6A and 6B show plating various shapes or features across multiple layers, including (moving from left to right): (i) a box shield 181 (for shielding interference and undesired RF or EM signals), as shown a the left of the figure, (ii) conductive stumps or studs 140 stacked and interconnecting with or without routing or RDLs 135, (iii) an inductor 182, and (iv) on the right of the figure a power delivery or thermal dissipation structure 183. FIG. 6A also shows the second conductive layer 135b contacting second conductive contacts 140b.

FIG. 6B illustrates an additional conductive layer 135 being formed over the upper planar surface 143 of encapsulant 142 and conductive material 135.

In forming a molded substrate 80, 210, 220, or 230 there may be an encapsulating step for every conductive layer formed. Alternatively, a single encapsulant 142 may encapsulate more than one conductive layer 135 or vertical conductive contact 140 at a time such as encapsulating multiple conductive layers 135 which may form, comprise, or be a part of multiple different shapes and features (e.g., short features, medium features, and long or tall features), following which a grind step with grinder 129 may expose tall features while medium and short features are not exposed and remain covered by the encapsulant.

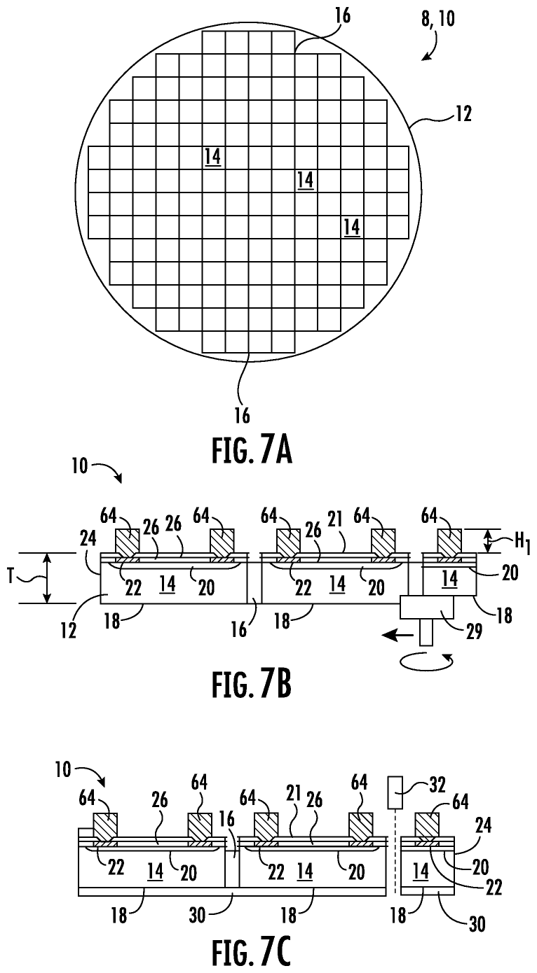

FIG. 7A shows a plan or top view of a substrate 8, which may comprise a semiconductor wafer or native wafer 10 with a base substrate material 12, such as, without limitation, silicon, silicon dioxide, silicon carbide, germanium, silicon germanium, gallium arsenide, indium phosphide, gallium nitride, silicon nitride, silicon carbide, or other semiconductor material for the base material or structural support. A plurality of components 14 including semiconductor components can be formed on wafer 10 and can be separated by a non-active, inter-component wafer area or saw street 16 as described above. The components 14 may differ from earlier components 60 where the components 14 of FIGS. 7A-7C may comprise embedded components 14 as part of a substrate core 1060 as shown in later figures, whereas components 60 are disposed external to the molded substrate 80 and coupled by way of conductive bumps, pads or solder. The saw street 16 can provide cutting areas to singulate the semiconductor wafer 10 into individual components 14 for later embedding into the substrate core 1060. In other instances, integrated passive devices (IPDs), either passive or active bridge chips, or other suitable devices that become embedded devices can be formed on a substrate 8 formed of glass, ceramic, or other suitable material for providing structural support for subsequent processing.

Each embedded component 14 may comprise one or more active devices, passive devices, or both active devices and passive devices. In some instances, the embedded component 14 may be formed without active and passive devices, and be used for transmission or routing, such as by comprising TSVs for vertical interconnect. For example, the embedded component 14 may be formed as a bridge chip with only electrical routing and with copper studs of the semiconductor chip electrically connected or coupled with wiring, routing, or RDL to the bridge chip. The embedded component 14 may also be only a dummy substrate with no electrical function, but rather act as structural element and may or may not include copper studs. In some embodiments, the embedded component 14 may not include, and may be formed without, conductive studs.

The embedded component 14 comprises semiconductor chips and semiconductor die that comprise a backside or back surface 18, an active layer 20 and a front surface 21 opposite the backside 18. In some instances, both the active layer 20 and the backside or back surface 18 of the embedded component 14 may be active. In any event, the embedded component 14 contains one or more analog, or digital circuits, diodes, or transistors implemented as active devices, conductive layers, and dielectric layers formed within or on the chip and electrically interconnected according to the electrical design and function of the semiconductor chip and may comprise a processor or logic device. In some instances, passive devices may also be integrated as part of the semiconductor chip or semiconductor die. The embedded component 14 may comprise circuits that may include one or more transistors, a FET, a JFET, a MOSFET, a BJT, an IGBT, a SIT, a Schottky transistor diodes, and other circuit elements formed within the chip substrate and close to the front surface 21 to implement analog circuits or digital circuits, such as DSP, ASIC, memory, or other circuits. Circuits may include RF circuits, LED, LCOS, CIS, transistor, optoelectronic, MEMS and the like. The embedded component 14 may also contain IPDs such as inductors, capacitors, and resistors, for RF signal processing, digital or analog power line control or other functions. The embedded component 14 may be formed on a native wafer. The embedded component 14 may be an optical component, connector or socket such as to easily couple or plug into a power supply or other desirable object.

FIG. 7B illustrates a cross-sectional view of a portion of semiconductor wafer 10 having a thickness, “t”. Each embedded component 14 is shown formed of base substrate material 12 and comprising a backside 18 or back surface, an active layer 20 and a front surface 21, opposite the backside 18.

An electrically conductive layer or contact pads 22 is formed over active layer 20 using PVD, CVD, electrolytic plating, electroless plating process, or other suitable metal deposition process. Conductive layer or contact pads 22 can be one or more layers of aluminum (Al), Titanium (Ti), copper (Cu), tin (Sn), nickel (Ni), gold (Au), palladium (Pd), silver (Ag), cobalt (Co), platinum (Pt), tungsten (W), or other suitable electrically conductive material. Conductive layer 22 operates as contact pads or bond pads electrically coupled or connected to the circuits, transistors, or diodes in the semiconductor substrate 10 near front surface 21. The conductive layer can be formed as contact pads 22 disposed side-by-side a first distance from an edge 24 of component 14, as shown in FIG. 1B. Alternatively, conductive layer can be formed as contact pads 22 that are offset in multiple rows such that a first row of contact pads 22 is disposed a first distance from the edge 24 of the component 14, and a second row of contact pads 22 alternating with the first row is disposed a second distance from the edge 24 of the component 14. In other instances, the embedded component 14 can comprise digital chips, analog chips, or RF chips (or other chips) with more than two rows of contact pads and may further comprise contact pads 22 over the whole surface of the chip that do not follow a full grid pattern. Other components 14 may have contact pads in an array over the whole surface of the chip.

FIG. 7B also illustrates the semiconductor substrate 10 and components 14 can undergo an optional thinning or grinding operation with grinder 29 to reduce a thickness, t of the semiconductor substrate 10 and component 14 to form a component 14 having a thickness which has been reduced. Other methods to reduce the thickness of the semiconductor substrate 10 such as diamond bit cutting, plasma etching or wet etching, as an alternative to, or in combination with, the optional grinding operation may be used and selection of the thinning process may depend on which base substrate material 12 the component 14 is made from.

FIG. 7B further shows one or more optional insulating, passivating, or dielectric layers 26 which may be conformally applied over active layer 20 and over conductive layer comprising contact pads 22. Insulating layer 26 can include one or more layers that are applied using PVD, CVD, screen printing, spin coating, spray coating, sintering, thermal oxidation, or other suitable process. Insulating layer 26 can contain, without limitation, one or more layers of silicon dioxide (SiO2), carbon-doped silicon dioxide, silicon nitride (Si3N4), silicon oxynitride (SiON), tantalum pentoxide (Ta2O5), aluminum oxide (Al2O3), polymer, polyimide, benzocyclobutene (BCB), polybenzoxazoles (PBO), or other material having suitable insulating and structural properties. When insulating layer 26 is formed over conductive layer comprising contact pads 22, openings are formed completely through insulating layer 26 to expose at least a portion of conductive layer for subsequent mechanical and electrical interconnection using contact pads 22. In alternate embodiments, insulating layer 26 includes a passivation layer and conductive layer comprising contact pads 22 may be formed atop the insulating layer 26. In such an embodiment, no openings in the insulating layer 26 over contact pads 22 would be necessary. In some embodiments, insulating layer 26 includes a passivation layer forming front surface 21. In other embodiments where the conductive layer comprising contact pads 22 is not covered by insulating layer 26, front surface 21 may comprise the conductive layer.

FIG. 7B shows conductive studs or electrical interconnect structures 64 can be formed as bumps, thick pads, columns, pillars, posts, or conductive studs and are disposed over, and coupled or connected to, contact pads 22. The conductive studs 64 can be formed directly on contact pads 22 using patterning and metal deposition processes such as screen printing, PVD, CVD, sputtering, electrolytic plating, electroless plating, evaporation, or other suitable metal deposition process. Alternately, conductive studs 64 may be formed in a position not vertically over the contact pads 22 and connected by RDL. Conductive studs 64 can be one or more layers of Al, Cu, Sn, Ni, Au, Ag, W, palladium (Pd), or other suitable electrically conductive material and can include one or more UBM layers. In an embodiment, a photoresist layer can be deposited over component 14 and contact pads 22. A portion of the photoresist layer can be exposed and removed by a developing or other suitable process. Exposure could be through a mask or with a direct writing tool like a laser or e-beam. Electrically conductive studs 64 can then be formed as pillars or other structures as previously described in the removed portion of the photoresist and over contact pads 22 using a plating process. In some embodiments, copper may be used in a plating process. The photoresist layer and other appropriate layers, such as a seed layer, can be removed leaving conductive studs 64 that provide for subsequent mechanical and electrical interconnection and a standoff with respect to active layer 20 and insulating layer 26 if present. In some instances, the conductive studs 64 include a height, H1, in a range of 3-100 micrometers (μm), 5-50 μm, 10-40 μm, or about 25 μm. In some instances, the height H1 of the conductive studs 64 may be less than 5 μm or less than 3 μm.

A conductive stud 64 is a conductive interconnect structure that may have generally vertical sides and may be wider than it is tall, built-up on a substrate, such as over an active layer of a chip, polyimide, or mold compound. A conductive stud, though typically formed of the same materials as a pillar or post would be formed, may differ from a pillar or post, each of which may have a height greater than its width. A conductive stud, though it is commonly formed in a cylindrical shape, may be formed with a cross-sectional area that is circular, oval, octagonal, or as any polygonal or other shape and size. Another use for a conductive stud is as a dummy thermal conductive stud that is not electrically coupled to an active electrical circuit but is instead thermally coupled to a heat source of an active device to conduct or dissipate the heat to another structure, such as to a die pad on a surface of the component 14. The generally vertical sides of a conductive stud 64 are different from the sides shape that exists for a solder ball or a compressed or outwardly deformed solder ball that has generally rounded sides. The generally vertical nature of a conductive stud 64 comes from being formed in a structure that has been previously developed or etched, such as within openings in a photoresist layer, which will also be generally vertical, although it may comprise imperfections or irregularities in shape that result from the etching process, the photoresist material, or other materials and processes used. For example, developing or etching does not generally perfectly or uniformly remove the photoresist within the openings, and therefore forms imperfect, generally vertical openings for deposition of conductive materials for the conductive stud 64. The term “generally vertical” as used herein includes perfectly vertical and imperfectly vertical sides. A conductive stud is not a wire bond and is not solder.

FIG. 7C further illustrates an optional adhesive or a (chip) die attach film (DAF) or material 30 may be attached to the back surface 18 of the semiconductor substrate or wafer 10, such as for subsequent mounting on a carrier. FIG. 7C also illustrates wafer 10 can be singulated with a saw or wafer cutting tool 32 into individual components 14 through saw streets 16 using a saw blade or laser cutting tool or plasma dicing tool or laser stealth dicing process or a scribe and break process. In some instances, the components 14 will have a thickness, t of between about 10 μm to about 300 μm for thin ground wafers, and about 10 μm to about 800 μm for thick ground wafers. In other instances, the components 14 will have a thickness of between about 20 μm to about 200 μm for thin ground wafers, and about 100 μm to about 700 μm for thick ground wafers. In further instances, the wafer 10 may not be subjected to backgrinding and may comprise a full thickness, t, of from about 760 to 800 μm, or about 780 μm for a wafer 10 having a diameter of 300 mm.

While FIGS. 7B, 7C, 8C, 10 and 11 depict conductive studs or conductive interconnects 64, in other embodiments, embedded components 14 may be provided without conductive studs 64. In such embodiments, embedded components 14 may be disposed over a temporary carrier and formed according to the methods and embodiments following.

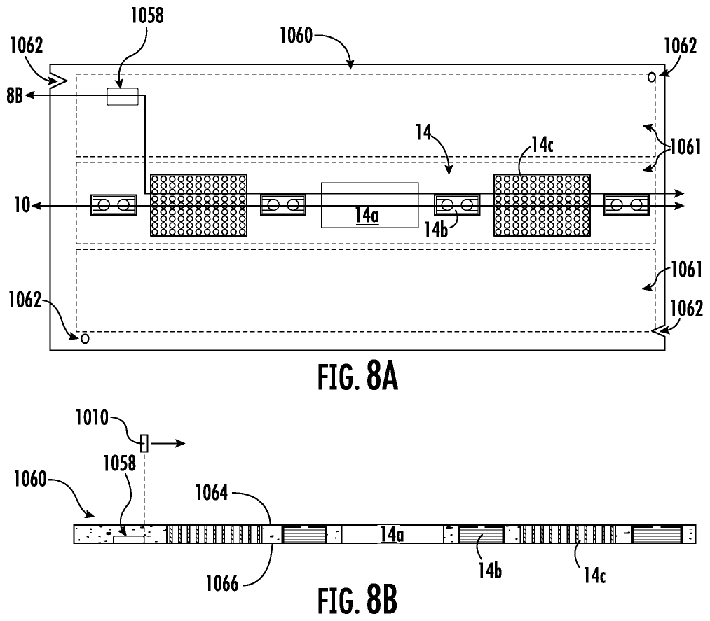

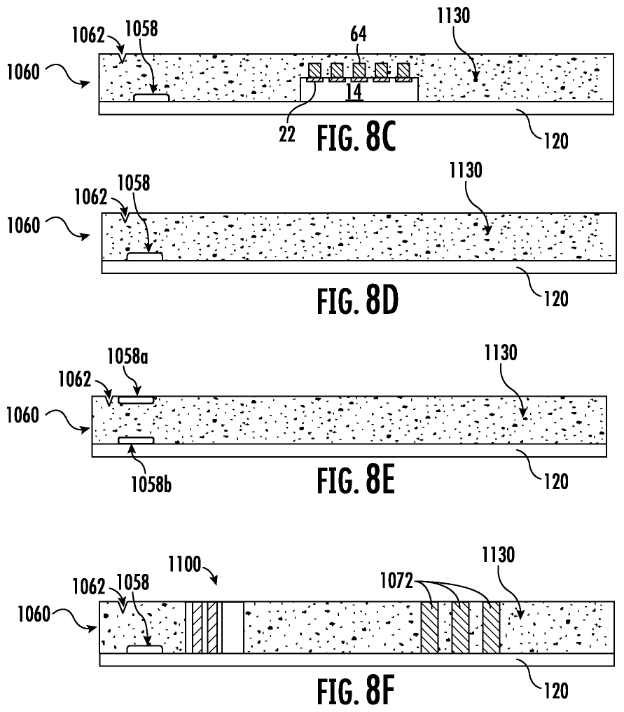

FIG. 8A illustrates providing a substrate core 1060 having alignment features 1062 disposed therein, additional detail of which is discussed herein. While substrate core 1060 is shown in a rectangular shape, a POSA will understand that substrate core 1060 may be provided in any geometric or organic shape, such as circular or round, oval, square, polygonal, and other similar shapes. The substrate core 1060 may comprise a composite core (e.g., comprising PCB, or a laminate core with build-up layers) and may also comprise a molded core.

The substrate core 1060 may comprise a core, a glass fiber woven material or core, layers of glass fiber, a glass reinforced epoxy material such as FR4, CEM, plastic, polymer, encapsulant or mold compound (either with or without fillers) such as epoxy or a thermoset material formed by a molding process, a printed circuit board (PCB) with or without routing, a PCB core, glass, metal, ceramic, silicon, fiberboard (for example cardboard), layers of paper laminated with epoxy or phenolic resin, carbon fiber, composite, or other suitable material. As used herein FR4 further comprises any suitable Flame Retardant PCB material such as FR1, FR2 or FR3; and similarly, CEM further comprises CEM1, CEM2 or CEM3. According to some embodiments, the method of making a molded interconnect substrate may comprise providing an unreinforced core 1060 comprising an organic material. In further embodiments, the unreinforced core 1060 as disclosed herein is formed without reinforcement and as such does not comprise prepreg, FR-4, bismaleimide-triazine (BT), glass fibers, carbon fibers or other similar fibrous reinforcements. In some instances an unreinforced core 1060 may comprise an encapsulant or mold compound with filler, such as 85% or more filler by volume. Prepreg as known the art comprises a glass fiber weave or cloth impregnated with a resin bonding agent. In an embodiment, the embedded components 14 may comprise one or more of a first component 14a, a second component 14b and a third component 14c, comprising at least one of active components, a chip, a die, passive components, glass, ceramic, embedded capacitors, deep trench capacitors, inductors, bridge die, voltage regulators, RF components. While shown as disposed within one component placement area 1061, a person of ordinary skill in the art (POSA) would understand that any of the embedded components 14 may be disposed in any of the component placement areas 1061 as shown in FIG. 8A.

FIG. 8A further shows the substrate core 1060 comprising at least one alignment feature 1062 disposed on a surface or through a thickness of the substrate core 1060, at an edge or around a periphery of substrate core 1060. Alignment feature 1062 may comprise a notch, a hole, or any type of feature incorporated into substrate core 1060 which may be used as a location reference for subsequent alignment. According to some embodiments, substrate core 1060 may comprise a tracking identifier 1058. Tracking identifier 1058 may comprise a device, such as an inductor, antenna, RFID component or a directional component, such as an accelerometer, able to determine an orientation in space of the substrate core 1060. The tracking identifier 1058 may be interrogated by a reader 1010 that determines the orientation of substrate core 1060 by measuring signal strength, where a stronger signal strength is measured when the reader is closer to the tracking identifier 1058, such as when the tracking identifier 1058 is disposed on or within a surface of the substrate core 1060. The reader may be connected to a computer which records the 3D position in space, number of flips, process history, and similar data for the substrate core to track the substrate core 1060 during processing. In so doing, the tracking identifier 1058 retains processing information such as the number of iterations of a given process step applied to the substrate core 1060. For example, if substrate core 1060 is subject to a rotation or a flip about a long axis, the tracking identifier may count that rotation or flip at a first instance, and a second flip as part of a second process may be added to the count. The tracking identifier 1058 may be read to verify completion of process steps and ensure manufacturing consistency. For ease of readability through multiple encapsulant layers, substrate core 1060 may comprise disposing a first tracking identifier 1058a on or within a front side of the substrate core 1060, and disposing a second tracking identifier 1058b on or within a back side of the substrate core 1060, as depicted in FIG. 8E.

The tracking identifier 1058 may also accumulate information during processing (by writing to its memory) such as the date and time of processing, one or more processing locations, conditions of processing, and what is included in the assembly. The tracking identifier 1058 may also comprise security or authentication features that can prevent the assembly from functioning.

Tracking identifier 1058 may comprise any of, or a plurality of, a 2-dimensional (2D) code such as a 2D code comprising a data matrix, a lasermark, a witness mark, an ink mark, an inductor, an antenna, an RFID component, or a directional component. According to some embodiments, the tracking identifier 1058 comprising the 2D code comprising the data matrix, the laser mark or the ink mark may be read by a reader or detector, removed by planarizing an encapsulant layer, and applied in a same or different manner than originally applied. According to some embodiments, the tracking identifier 1058 may comprise a directional component formed of a piece of metal or magnetic material that can be tracked based on magnetism or by another suitable force. According to some embodiments as disclosed herein, the substrate core 1060 may comprise a thickness in a range of 0.4 mm to 0.9 mm. According to additional embodiments as disclosed herein, the substrate core 1060 may comprise a coreless substrate having a thickness of about 0.075 mm. In yet further embodiments, the substrate core 1060 may comprise a thickness in a range of from 0.05 mm to 3 mm, and in some embodiments from 0.05 mm to 1 cm in thickness.

FIG. 8B shows a cross-sectional view of the related section line of FIG. 8A, depicting substrate core 1060 having a front side of the substrate core 1064, a back side of the substrate core 1066, and tracking identifier 1058 disposed therein. Embedded component 14 is further shown disposed within substrate core 1060. While according to this embodiment, one embedded component 14 is shown, a person of ordinary skill in the art (POSA) would understand that any number of embedded components 14 may be disposed within substrate core 1060. In some embodiments, one or both of the front surface 21 and backside 18 of the embedded components 14 may be covered by residual material comprising at least a portion of the substrate core 1060, such as encapsulant or mold material, glass fibers, epoxy or phenolic resin, or polymeric materials remaining from embedding the embedded components 14 into the substrate core 1060. As part of the planarization processes as disclosed herein, the residual material may be removed to expose either or both of contact pads 22 and conductive interconnects 64 for electrical connection. According to further embodiments, a laser ablation process may be used, whether separately or in combination with the planarization process, to form vias over, and expose either or both of contact pads 22 and conductive interconnects 64 of the embedded components 14 for subsequent electrical connection. Additionally, the embedded components 14 may be formed as part of a wafer fabrication process with electrically conductive layers or contact pads 22 having an increased thickness beyond what is typical, or an additional conductive layer formed thereon, to ensure that contact pads 22 have sufficient thickness remaining after the laser ablation process, and also to provide a stopping point to prevent damage to the embedded components 14. Subsequent electrical connection to the electrically conductive layers or contact pads 22 may be provided by a sputtered seed layer and formation of the first conductive layers or first patterned conductive layers 1068 and 1078 atop the contact pads 22.

FIGS. 8C-8F illustrate non limiting exemplary embodiments of the substrate core 1060 comprising a mold compound or encapsulant 1130, alignment features 1062, vertical interconnects 1072 and 1100, and tracking identifiers 1058 disposed therein, disposed over a temporary carrier 120. While temporary carrier 120 is shown in FIGS. 8C-8F, FIGS. 9A-FIG. 11 are shown without temporary carrier 120 for simplicity, a POSA will understand that temporary carrier 120 may be present as part of the method, while not depicted.

FIG. 8C shows where the substrate core 1060 comprises an encapsulant 1130 formed by a molding process. According to some embodiments as shown in FIG. 8C, the substrate core 1060 may comprise at least one embedded component 14 further comprising vertical interconnects 64 disposed atop contact pads 22. Embedded components 14 may comprise at least one of active components, a chip, a die, passive components, embedded capacitors, deep trench capacitors, inductors, single-sided bridge die or double-sided bridge die, voltage regulators, optical components, opto-electronic components, RF components, conductive posts or conductive interconnects 1072 and vertical interconnect blocks 1100 (VIBs). In some embodiments, the substrate core may include embedded components 14 comprising at least one double sided bridge die or interposer comprising through silicon vias (TSVs) or other vias formed in another suitable material that is not silicon. However, for convenience and ease of description, all vias may be referred to herein collectively as TSVs.

FIG. 8D illustrates a substrate core 1060 comprising an encapsulant 1130 formed by a molding process where the substrate core 1060 does not comprise an embedded component 14. According to an embodiment as shown in FIGS. 8C-8E, the substrate core 1060 comprises a tracking identifier 1058 disposed within the substrate core 1060.

FIG. 8E shows an embodiment of a substrate core 1060 comprising an encapsulant 1130 formed by a molding process, where the substrate core 1060 comprises at least one tracking identifier 1058. In some embodiments, the substrate core 1060 may not comprise at least one tracking identifier 1058, and instead the tracking identifier 1058 may be disposed in any of the encapsulant or build-up layers as disclosed following. As shown in FIG. 8E the method of making a molded core substrate may comprise disposing a first tracking identifier 1058a on or within a front side of the substrate core 1060 and disposing a second tracking identifier 1058b on or within a back side of the substrate core 1060. The tracking identifiers 1058 may be disposed on a surface of either side of substrate core 1060, below the surface of either side of substrate core 1060, or generally located proximal to surfaces of either side to simplify reading of tracking identifiers 1058.

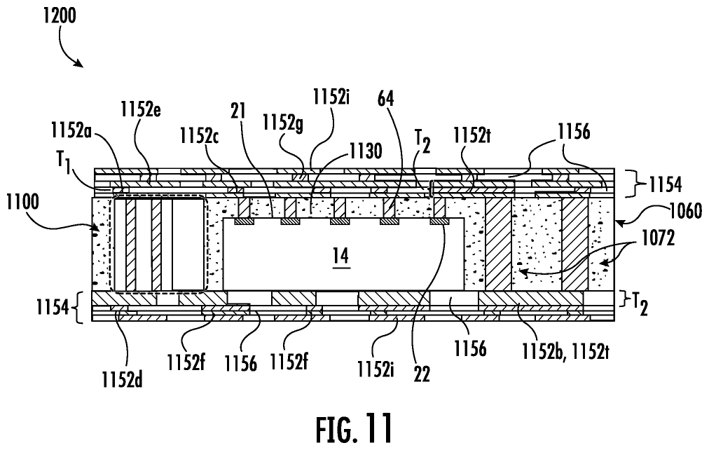

FIG. 8F depicts an exemplary substrate core 1060 comprising conductive vertical interconnects 1072 and a vertical interconnect block (VIB) 1100. The conductive vertical interconnects 1072 may be formed as described with reference to FIG. 11, and in a similar manner using similar materials as the first vertical conductive contacts 140. The VIB 1100 provides electrical interconnection vertically through the substrate core 1060 and is disclosed in U.S. Provisional patent Ser. No. 18/545,927, entitled “Semiconductor Assembly Comprising a 3D Block and Method of Making the Same” which was filed on Dec. 19, 2023, the entire disclosure of which is hereby incorporated herein by this reference. Although not depicted in FIG. 8F, a POSA will understand that additional vertical interconnects and combinations thereof may be disposed within the substrate core 1060. According to some embodiments, the method may comprise forming at least one vertical interconnect through a thickness of an unreinforced substrate core where the vertical interconnect comprises at least one vertical interconnect formed through a thickness of the unreinforced substrate core, where the vertical interconnect comprises at least one of a conductive post or conductive interconnect 1072, a vertical interconnect block (VIB) 1100, a vertical conductive contact, a conductive stump, a vertical connecting element, and a via, where the via comprises any of the types of vias as disclosed herein.

In some embodiments, the substrate core 1060 may further comprise an embedded component 14, and in some embodiments, THE substrate core 1060 may be formed without an embedded component 14. A POSA will understand that additional combinations of the features beyond those depicted in FIGS. 8C-8F are possible.

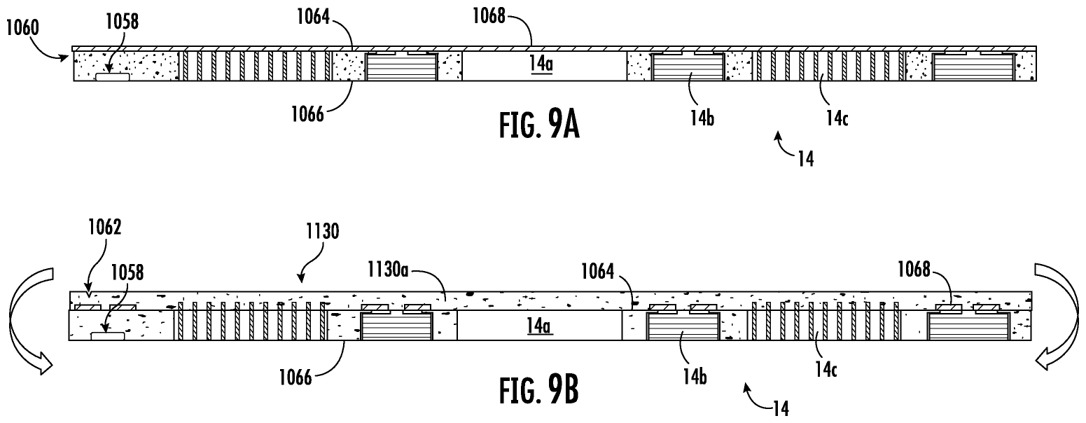

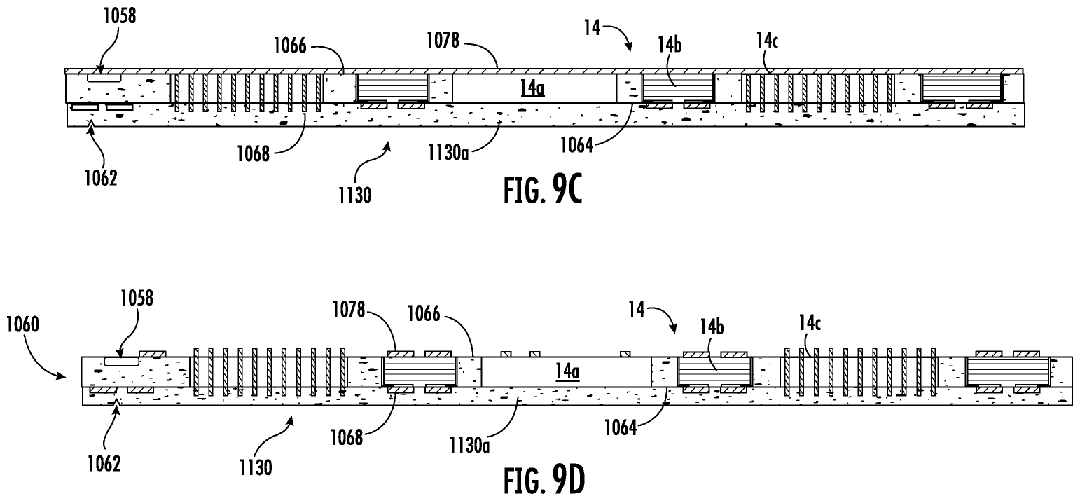

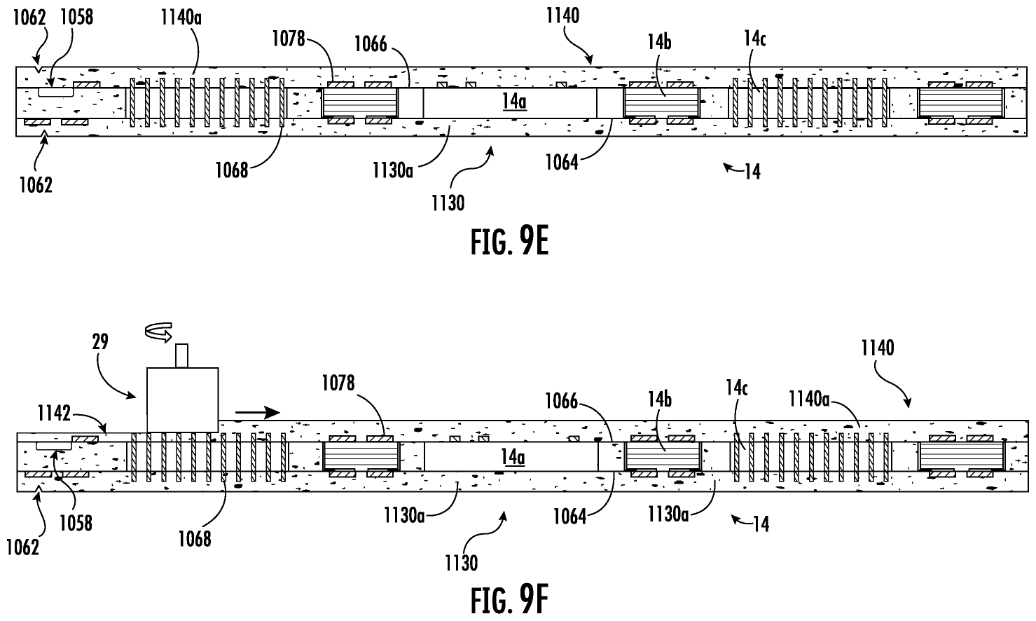

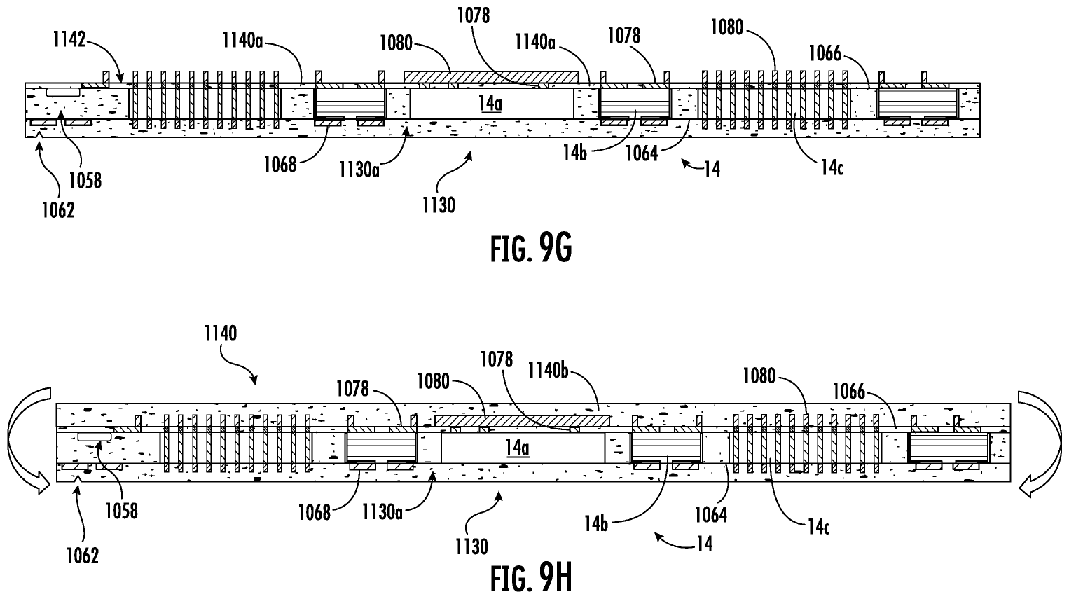

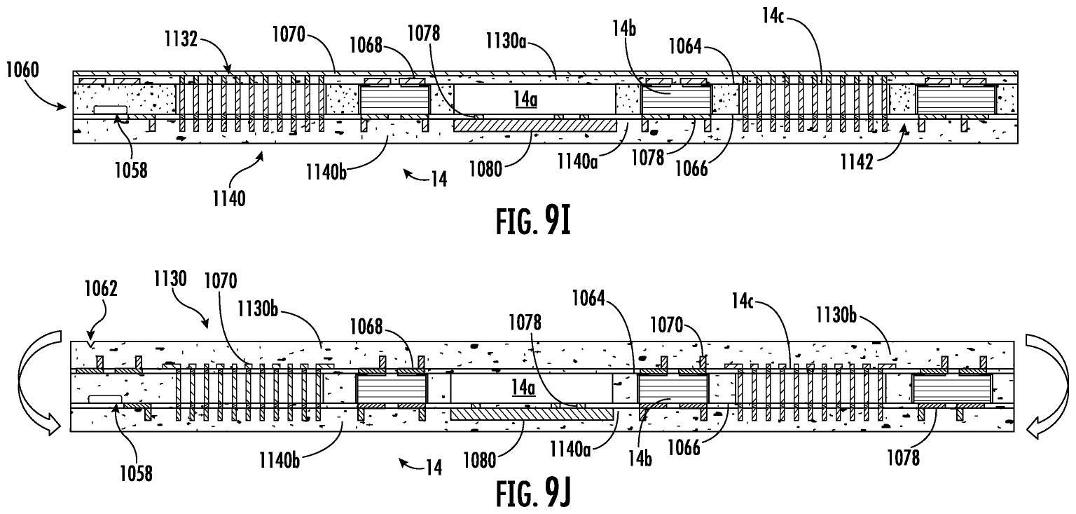

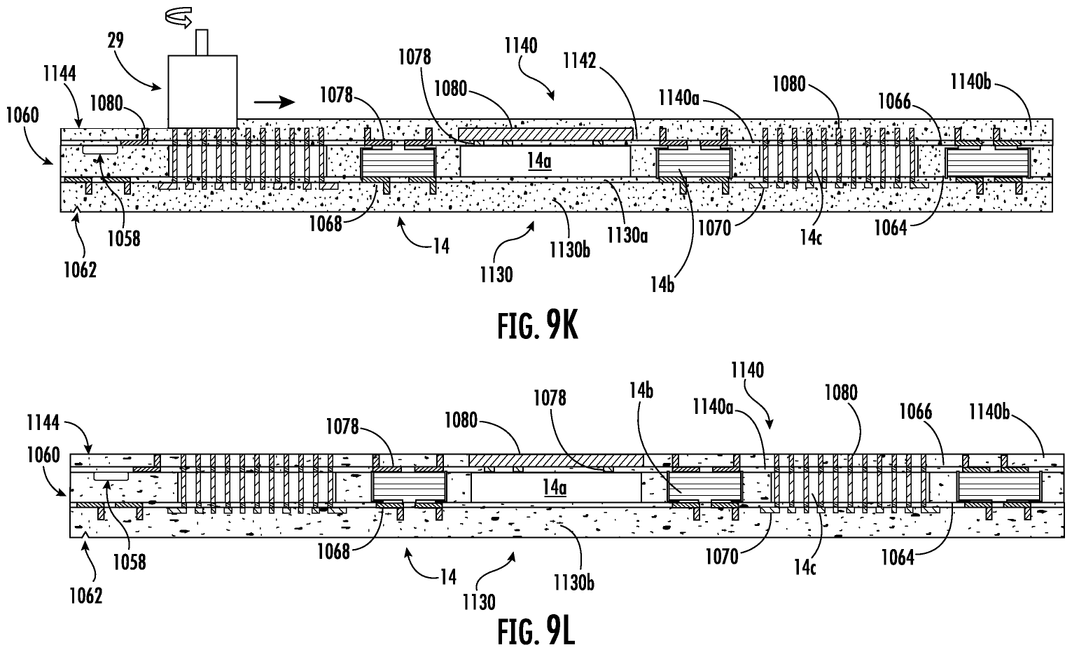

FIGS. 9A-9L illustrate various stages of forming a molded core substrate 1160, which may be formed over a substrate or temporary carrier 120. As shown in FIG. 9A, the method of making a molded core substrate 1160 comprises providing a substrate core 1060 and forming a first frontside conductive layer 1068 over a front side 1064 of the substrate core 1060. A planarizing process as further detailed herein may be performed on the front side 1064 of the substrate core 1060 prior to forming the first frontside conductive layer 1068 in order to ensure that after deposition, the first frontside conductive layer 1068 is sufficiently flat to ensure reliable assembly and robust electrical interconnection between conductive layers. In some embodiments, the planarizing process may similarly be applied to the back side 1066 of the substrate core 1060 such that the substrate core 1060 may comprise a front side 1064 and a back side 1066, both of which are planarized to a roughness of from 5 nanometers (nm) to 500 nm over a characteristic measurement distance. According to some embodiments, the substrate core 1060 may comprise at least one tracking identifier 1058 disposed therein. A POSA will understand that any of the additional embodiments of substrate core 1060 as shown and described for FIGS. 8C-8F could be provided as part of the method shown in FIGS. 9A-9L.

The first frontside conductive layer 1068 may further comprise a first patterned frontside conductive layer 1068. The first patterned frontside conductive layer 1068 may be formed by an additive process or by a subtractive patterning process is used. The subtractive patterning process may comprise first disposing the first frontside conductive layer 1068 over the front side 1064 of the substrate core 1060, the method may then further include patterning the first frontside conductive layer 1068 to form a first patterned frontside conductive layer 1068 comprising at least one of conductive traces, vias, lands, planes, lines and pads. Patterning any of the conductive layers as disclosed herein may be performed after deposition of the conductive layers, using a subtractive process, or more typically, patterning during deposition of the conductive layers by building up features as part of the conductive layers within a photoresist pattern. The first frontside conductive layer 1068 may further comprise forming first vertical interconnects 140 (shown e.g. in FIG. 2F), such as conductive stumps, vias and other vertically oriented connectors formed as part of the first frontside conductive layer 1068. Any of the conductive layers as disclosed herein may comprise forming first vertical interconnects 140, such as conductive stumps, vias and other vertically oriented connectors. The first conductive layer 1068 and first vertical interconnects 140 may be formed using PVD, CVD, electrolytic plating, electroless plating, or other suitable metal deposition process. The first conductive layer 1068 and first vertical interconnects 140 may be one or more layers of copper (Cu), aluminum (Al), tin (Sn), nickel (Ni), gold (Au), silver (Ag), titanium (Ti), Platinum (Pt), Tungsten (W) or other suitable electrically conductive material. The first conductive layer 1068 can be formed as one or more traces or as an RDL comprising a trace line and space of less than or equal to 2 μm for a pitch of less than or equal to 4 μm, or in other instances comprising a trace width of 1 μm and space of less than or equal to 2 μm. Larger pitches and less dense connections are also possible within the conductive layers as disclosed, such as for forming solid or mesh power and ground planes. The disclosure relating to the first conductive layer 1068 also applies to additional conductive layers as disclosed herein.

In some embodiments, the first frontside conductive layer 1068 may be configured to be electrically coupled to the at least one embedded component 14 over a front side 1064 of the substrate core 1060.

The method of making a molded core substrate 1160 as shown in FIG. 9B further comprises disposing a frontside encapsulant 1130 comprising a first frontside layer 1130a of encapsulant or molded dielectric over the front side 1064 of the substrate core 1060, over the at least one component 14, and over the first frontside conductive layer 1068. The frontside encapsulant 1130 and backside encapsulant 1140 (as depicted in FIG. 9E following) forming the encapsulant layers as disclosed herein may comprise a mold compound, a composite material, such as epoxy resin with filler, epoxy acrylate with filler, polytetrafluoroethylene, ABF, or other low k dielectrics. In some embodiments as depicted in FIGS. 8C-8E, the substrate core 1060 may be formed of encapsulant 1130 comprising a mold compound, a composite material, such as epoxy resin with filler, epoxy acrylate with filler, polytetrafluoroethylene, ABF, or other dielectrics, including low k dielectrics.

In some instances, it may be desirable to deposit SiO₂ inorganic dielectric on an encapsulant, such as that within substrate core 1060, frontside encapsulant 1130, backside encapsulant 1140, or on any other layer of encapsulant or mold compound. In doing so, the encapsulant may comprise silica filler, including 85% or more silica filler. After exposing the filler, such as by grinding to form a planar or flat surface, a majority or significant portion of the planar surface will be exposed SiO₂. The exposed SiO₂ filler can provide a good base and good adhesion for the deposition of the SiO₂ layer over, contacting, or on top of the exposed SiO₂ filler; and can also provide good overall adhesion of the deposited SiO₂ inorganic dielectric to the encapsulant. This adhesion between the exposed SiO₂ filler and the SiO₂ inorganic dielectric layer is unlike other applications where depositing an SiO₂ layer on a full plastic film (without SiO₂ filler) would result in a weaker adhesion between the layers.

In some embodiments, the method further comprises forming at least one alignment feature 1062 in or on a surface of the encapsulant 1130. After disposition of encapsulant 1130, the method comprises flipping the substrate core 1060 such that a back side 1066 of the substrate core 1060 is configured for processing. While in FIG. 9B a single first frontside layer 1130a of encapsulant is shown as disposed over the front side 1064, followed by flipping the substrate core 1060, a POSA will understand that the substrate core 1060 may not be flipped after disposition of each layer of encapsulant and conductive layers. For example, two thin conductive layers for signal routing may be disposed on the substrate core 1060, followed by flipping the substrate core 1060 to form a single thick conductive layer on an opposing side of the substrate core such as for power distribution. Accordingly, multiple layers may be formed on the same side of the substrate core 1060 before flipping to an opposing side.

Further, in some instances, one or more other dielectric layers, comprising polyimide or PBO or other suitable dielectric, may be disposed before, and under, or in other instances in place of the first frontside molded dielectric layer 1130a, such as to improve electrical performance of the first front side patterned conductive layer 1068.

FIG. 9C illustrates forming a first backside conductive layer 1078 over the back side 1066 of the substrate core 1060. As similarly done for the first frontside conductive layer 1068, a planarizing process as disclosed herein may be performed on the back side 1066 of the substrate core 1060 prior to forming the first backside conductive layer 1078 in order to ensure that after deposition, the first backside conductive layer 1078 is sufficiently flat for the aforementioned reasons of reliability and robust electrical connection. According to some embodiments, the first backside conductive layer 1078 may be configured to be electrically coupled to the at least one component 14. As depicted by FIG. 9C, forming a conductive layer opposite a fully encapsulated layer protects the underlying conductive layers disposed within the encapsulant from damage during any processing used to form the conductive layers.

By alternating the formation of build-up layers between the frontside and the backside (or from one side to another), such as frontside encapsulant 1130 and backside encapsulant 1140, first frontside conductive layer 1068 and first backside conductive layer 1078, second frontside conductive layer 1070 and second backside conductive layer 180 (or any number of layers), warpage may be controlled by counter-balancing layers on alternating sides. The formation of any of the above layers over the core 1060 will introduce some stress that results in warpage. However, the stress and thus the warpage can be managed, counterbalanced, and reduced, by alternately layering the layers over the core 1060. In various instances, the layers' thickness, material, stiffness (modulus of elasticity) will be accounted for to manage the stress and warpage. In some cases, a dielectric layer will be deposited primarily as a stress management layer with less regard to its effect on electrical performance.

As shown in FIG. 9D, the method further comprises patterning the first backside conductive layer 1078 to form a first patterned backside conductive layer 1078 comprising at least one of conductive traces, vias, lands, planes, lines and pads. The patterning may be accomplished by patterning a film or resist layer before the first backside conductive layer 1078 is formed in openings thereof; or alternatively the first patterned backside conductive layer 1078 may be formed by etching or removing a portion of the first backside conductive layer 1078. In order to balance warpage and thermal performance of the substrate core 1060 during use, the first frontside conductive layer 1068 comprises a first surface area, and the first backside conductive layer 1078 comprises a second surface area, and the first area and the second surface area differ in an amount by area less than 50% or less than 30%. Balancing respective surface areas of the first and second conductive layers allows for more effective thermal management and reduced substrate warpage during assembly. Such balancing of the total surface area of conductive layers would similarly apply to any subsequently formed conductive layers.

According to FIG. 9E, the method comprises disposing a first backside encapsulant 1140, comprising a first backside layer or a backside molded dielectric layer 1140a over the back side 1066 of the substrate core 1060, over the at least one component 14, and over the first backside conductive layer 1078. In some embodiments, the method further comprises forming at least one alignment feature 1062 in or on a surface of the encapsulant 1140.

FIG. 9F shows planarizing, using grinder 29, the first backside layer of encapsulant 1140a by grinding. Alternatively the planarizing can be performed by chemical mechanical polishing (CMP), surface planarization, polishing, plasma etching, wet etching, or planarizing by using a diamond-based cutter, surface planarization, or polishing, to expose at least a portion of the first backside conductive layer 1078 to form a first backside planar surface 1142 on the first backside layer of encapsulant 1140a. In some embodiments, planarizing the first backside layer of encapsulant 1140a may comprise any combination of the above-referenced processes to form the first backside planar surface 1142, such as for example a grinding process followed by a surface planarization process. Planarizing or grinding the encapsulant forms a planarized encapsulant surface for subsequent deposition of conductive layers forming feature sizes of small dimension, such as vias having a diameter of from 0.75 μm to about 1.5 μm, or about 1 μm, trace widths in a range of about 0.5 μm to about 2 μm, or about 1 μm, and a space between traces in a range of about 1 μm to about 2 μm. The planarizing or grinding of the encapsulant produces a flatness of within a range of about 0.5-5 micrometers and a total roughness height from peak to valley measured over a characteristic measurement distance of 1 millimeter (mm) length of between 5 and 500 nanometers (nm). While conventional encapsulant grinding might be done with less flatness, greater accuracy and precision can be obtained by using integrated sensors such as laser, acoustic, or other non-contact methods to control the grinding resulting in better flatness. According to embodiments as disclosed herein, at least one of a first frontside planar surface 1132, a second frontside planar surface 1134, a first backside planar surface 1142 and a second backside planar surface 1144 may be planarized to a surface roughness within 5 to 500 nanometers.

FIG. 9G illustrates forming a second backside conductive layer or second patterned backside conductive layer 1080 over the first backside planar surface 1142, the second backside conductive layer 1080 configured to be electrically coupled to the first backside conductive layer 1078. The method further comprises patterning the second backside conductive layer 1080 to form a second patterned backside conductive layer comprising at least one of conductive traces, planes, vias, lands, lines, and pads. In some instances, the second patterned backside conductive layer may comprise or primarily comprise, a plane and vias. In some embodiments, the second backside conductive layer 1080 may comprise forming vertical interconnects, such as conductive stumps, vias and other vertically oriented connectors formed over the first backside conductive layer 1078. According to some embodiments, the second backside conductive layer 1080 may be electrically coupled to the at least one component 14.

As shown in FIG. 9H, the method comprises disposing a second backside layer of encapsulant 1140b over the second backside conductive layer 1080 and the backside planar surface 1142. After disposition of the second backside layer of encapsulant 1140b, the method further includes flipping the substrate core 1060 such that the first frontside layer of encapsulant 1130a is configured for processing.

As similarly disclosed for FIG. 9F, FIG. 9I shows planarizing the first frontside layer of encapsulant 1130a by grinding, chemical mechanical polishing (CMP), surface planarization, or polishing, to expose at least a portion of the first frontside conductive layer 1068 to form a first frontside planar surface 1132 on the first frontside layer of encapsulant 1130a. According to some embodiments, the grinding process of FIG. 9I may remove alignment feature 1062 from first frontside layer of encapsulant 1130a, which may be applied to subsequent layers of frontside encapsulant 1130 or backside encapsulant 1140, whether before or after the planarizing step removing the alignment feature 1062. As further shown in FIG. 9I, a second frontside conductive layer or second patterned frontside conductive layer 1070 may be formed over the first frontside planar surface 1132, the second frontside conductive layer 1070 configured to be electrically coupled to the first frontside conductive layer 1068 or the at least one component 14. In some embodiments, the second frontside conductive layer 1070 may be configured for electrical coupling to the first frontside conductive layer 1068 and the at least one component 14. As disclosed for FIGS. 9A and 9B, the method comprises patterning the second frontside conductive layer 1070 to form at least one second patterned frontside conductive layer comprising one or more of conductive traces, vias, lands, planes, mesh, lines, and pads.

According to FIG. 9J, the method includes disposing a second frontside layer of encapsulant 1130b over the second frontside conductive layer 1070 and the first frontside planar surface 1132, and flipping the substrate core 1060 such that the second backside layer of encapsulant 1140b is configured for processing.

As depicted in FIG. 9K and disclosed previously in a similar configuration of FIG. 9F, the method includes planarizing the second backside layer of encapsulant 1140b by grinding, chemical mechanical polishing (CMP), surface planarization, or polishing, to expose at least a portion of the second backside conductive layer 1080 to form a second backside planar surface 1144 over the first backside planar surface 1142 of the first backside layer of encapsulant 1140a. The planarization steps as disclosed herein may be performed on any of the layers of frontside encapsulant 1130 and backside encapsulant 1140, without limitation.

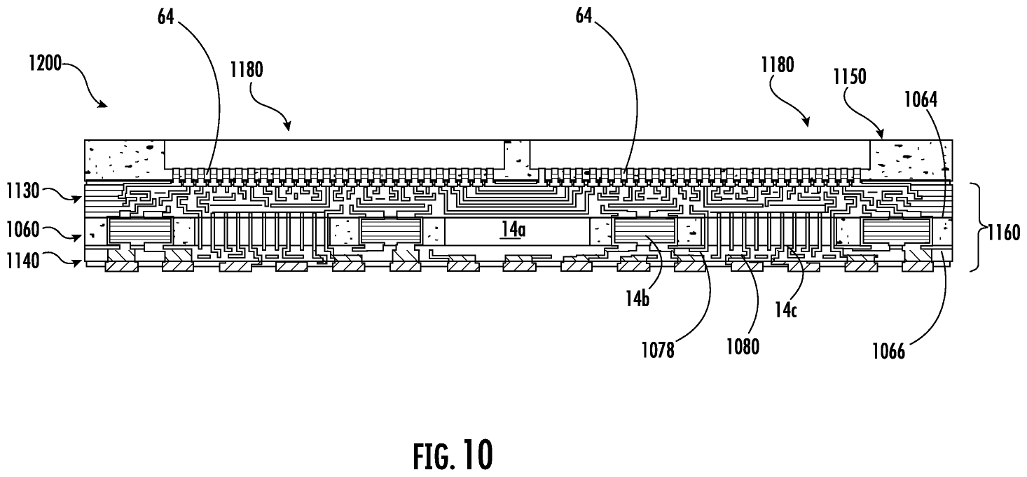

FIG. 9L illustrates a nearly fully assembled molded core substrate 1160 comprising multiple, alternating layers of encapsulants 1130, 1140 on a frontside 1064 and a backside 1066 of substrate core 1060, respectively. In some embodiments and as shown in FIG. 10 following, the method may comprise forming additional alternating layers of conductive frontside layers 1068, 1070 and conductive backside layers 1078, 1080, interleaved with alternating frontside layers of encapsulant 1130 and backside layers of encapsulant 1140, to form up to 12 layers or more of frontside encapsulant layers 1130 and backside encapsulant layers 1140. Any of the encapsulant or dielectric layers as disclosed herein may comprise the same or different materials on a same side or opposing sides of the substrate core 1060. Planarizing may occur after each layer of encapsulant is formed or disposed. Planarizing may also occur on either or both of the front side of the substrate core 1064, and the back side of the substrate core 1066, prior to forming either or both of the first frontside conductive layer 1068 and the first backside conductive layer 1078.

In some embodiments, the conductive frontside layers 1068, 1070 and conductive backside layers 1078, 1080 may be formed to comprise one or more power planes of a large dimension, a power delivery system, a thermal delivery system, shielding for all or part of the substrate, a ground plane, patterned metal in any shape, including shielding comprising a shape for inductors, passive components, antennas, and markings for identification. In some embodiments, the frontside conductive layers 1068, 1070, and backside conductive layers 1078, 1080, may not be formed in a 1:1 ratio on either side of the substrate core 1060. For example, the substrate core 1060 may comprise a front side 1064 having one frontside conductive layer 1068 formed thereon, and a back side of the substrate core 1066 having three, four or more backside conductive layers disposed thereon with the layers comprising different thicknesses. A POSA will understand that additional variations of conductive layers are possible.

According to some embodiments, the method may comprise forming the substrate core 1060 and the additional layers of frontside encapsulant 1130 and backside encapsulant 1140 from at least one mold compound using a molding process. The mold compound comprising the additional layers of frontside encapsulant 1130 and backside encapsulant 1140 may comprise at least one of a coefficient of thermal expansion (CTE), modulus of elasticity, and a glass transition temperature (Tg) that are substantially the same as one another. Advantageously, selecting frontside encapsulant 1130 and backside encapsulant 1140 having substantially the same properties of CTE, modulus of elasticity, and Tg may reduce warpage during the encapsulation processes of the method as disclosed. Reducing warpage during assembly may reduce overall package stress in the final molded core assembly 1200. In some instances, at least one of the frontside layer of encapsulant 1130 and backside layer of encapsulant 1140 may comprise one or more layers comprising polyimide (PI), PBO or other suitable organic dielectric disposed under at least a portion of a frontside or backside conductive layer, or in some cases replacing, 1068 and 1078, respectively. In further instances, at least one of the frontside layers of encapsulant 1130, and backside layers of encapsulant 1140, may be formed from a low dielectric constant material, such as polyimide, Teflon™, a laminated build-up film formed of low dielectric constant materials, and similar. As used herein, “about” or “substantially” means a percent difference less than or equal to 50% difference, 40% difference, 30% difference, 20% difference, 10% difference, or 5% difference.

In a view similar to the cross-sectional view of FIG. 8B, FIG. 10 illustrates a molded core assembly 1200 comprising the molded core substrate 1160. According to some embodiments, the substrate core 1060 and at least one of the first frontside layer of encapsulant 1130a, the second frontside layer of encapsulant 1130b, the first backside layer of encapsulant 1140a, the second backside layer of encapsulant 1140b and any additional layers, may comprise mold compounds that are formed by a molding process. The mold compounds may comprise a same mold compound having substantially the same properties of coefficients of thermal expansion (CTE), modulus of elasticity, and glass transition temperatures (Tg), or the mold compounds may comprise different materials yet having substantially the same properties of CTE, modulus and Tg. According to further embodiments, the substrate core 1060 may comprise a mold compound having a filler material of aluminum nitride (AlN), which has a higher thermal conductivity than that of silicon dioxide which is typically used in encapsulants and mold compounds. Graphene as a filler or additive to other fillers could also help with thermal conductivity. Other fillers have been used in mold compounds, and as such any suitable filler may also be used including calcium carbonate and aluminum oxide. A substrate core 1060, comprising a mold compound including AlN and formed by a molding process may provide enhanced thermal conductivity and thermal dissipation to embedded components 14 disposed therein.

In some embodiments, at least one of the first frontside conductive layer 1068, the second frontside conductive layer 1070, the first backside conductive layer 1078 and the second backside conductive layer 1080 are formed comprising at least one via having a diameter of from about 1 μm to about 2 μm, and a trace width in a range of about 0.5 μm to about 1 μm, and a space between traces in a range of about 1 μm to about 2 μm. According to some embodiments, any of the front or backside conductive layers as disclosed herein may comprise vias forming power and ground connections having a diameter of 5 μm to 25 μm. According to further embodiments, any of the front or backside conductive layers as disclosed herein may further comprise thermal vias having no electrical function or connectivity but providing enhanced thermal conductivity between the front or backside conductive layers. A POSA will understand that additional conductive layers beyond those disclosed herein may be formed, having similar via, line and space features as the frontside conductive layers and backside conductive layers as shown and described. At least a portion of the frontside conductive layers and backside conductive layers may be formed using “unit specific patterning,” which is also known under the trademark “Adaptive Patterning”®. Unit specific patterning or adaptive patterning is described, e.g., in U.S. Pat. No. 9,196,509, the entirety of which is hereby incorporated by reference herein.

In some embodiments, at least one of the outermost frontside conductive layers and the outermost backside conductive layers comprises pads for coupling to at least one peripheral device 1180. The peripheral devices 1180 may be disposed on one or both sides of the molded core substrate 1160. In some instances, the peripheral devices 1180 may be surrounded on at least four sides by peripheral encapsulant 1150. Peripheral encapsulant 1150 may have the same properties as encapsulants 1130, 1140 as disclosed herein, and formed by similar methods. In other instances, the peripheral devices 1180 may be flip-chipped and underfilled, they could also be die attached and wirebonded and then molded or encapsulated over. The peripheral devices 1180 comprise both chips as well as any suitable package or embedded device.

FIG. 11 illustrates an embodiment of a molded core assembly comprising a molded core substrate 1160 comprising an embedded component 14 having conductive interconnects or conductive studs 64 disposed thereon. The molded substrate 1160 may comprise at least one vertical interconnect block (VIB) 1100 disposed therein. As shown, the substrate core 1060 may further comprise conductive posts or conductive interconnects 1072 that may be formed within a resist layer (not shown) as columns, pillars, posts, bumps, or studs from copper or other suitable conductive material. The conductive interconnects 1072 can be formed using patterning and metal deposition processes such as printing, PVD, CVD, sputtering, electrolytic plating, electroless plating, metal evaporation, or other suitable metal deposition process. When conductive interconnects 1072 are formed by plating, a seed layer (not shown) can be used as part of the plating process. Conductive posts or interconnects 1072 can be one or more layers of Al, Cu, Sn, Ni, Au, Ag, Pd, solder, or other suitable electrically conductive material and can include one or more layers. The substrate core material may be disposed around the conductive posts or interconnects 1072.

Still referring to FIG. 11, the molded core substrate 1160 may comprise a build-up interconnect structure 1154 disposed over the front side 1064, and the back side 1066 of the substrate core 1060, where the build-up interconnect structure 1154 comprises one or more conductive layers 1152 and one or more insulating layers 1156. The conductive layers 1152 may vary in thickness from one layer to another. For example, for power applications where high current and thermal management are required, and high density routing such as for signal routing is also necessary, any of conductive layers 1152a, 1152c, 1152e, and 1152g may comprise a thickness, T1, of 1-2 μm for formation of thin traces having widths of similar dimension, where at least a portion of the conductive layers 1152 are patterned to vertically align with one another to form a stacked portion of a conductive layer 1152t, having a combined thickness T2, comprising the combined thickness of each of the conductive layers 1152a, 1152c and 1152e, as shown. In some embodiments for very high power applications, conductive layers 1152 may comprise power and ground layers, planes or meshed planes where high density signal routing is not necessary, and the build-up interconnect structure 1154 may comprise conductive layers 1152 comprising a thickness T2 of from about 7 μm to about 12 μm, or about 9 μm, and trace widths from about 200 μm to as large as about 1 mm, with spacing of about 300 μm. In addition to balancing respective surface areas of front and backside conductive layers as discussed with respect to FIG. 8D, it is similarly beneficial to balance a total volume of front and backside conductive layers disposed on opposing sides of the substrate core 1060. For example, similar to what is depicted in FIG. 11, if a thickness of the first frontside conductive layer 1068 is greater than a thickness of the first backside conductive layer 1078, the first backside conductive layer 1078 may comprise an surface area that is greater than that of the first frontside conductive layer 1078 such that a total volume of the first frontside conductive layer 1068 and the first backside conductive layer 1078 are substantially similar.

While this disclosure includes a number of embodiments in different forms, the particular embodiments presented are with the understanding that the present disclosure is to be considered as an exemplification of the principles of the disclosed structures, devices, methods, and systems, and is not intended to limit the broad aspect of the disclosed concepts to the embodiments illustrated. Additionally, it should be understood by those of ordinary skill in the art that other structures, manufacturing devices, and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art. As such, it will be evident that various modifications and changes may be made thereto without departing from the broader spirit and scope of the inventions as set forth in the appended claims. The specification and drawings are, accordingly, to be regarded in an illustrative sense rather than a restrictive sense. The above features and disclosure will be further understood in light of the claims included below.

What is claimed is:

1. A method of making a molded core substrate, comprising:
providing a substrate core having at least one tracking identifier disposed therein and comprising at least one embedded component, wherein:
the substrate core comprises one or more of: encapsulant, layers of glass fiber, a glass reinforced epoxy material such as FR4, CEM, plastic, polymer, mold compound such as epoxy or a thermoset material, a printed circuit board (PCB) with or without routing, a PCB core, metal, silicon, fiberboard, layers of paper laminated with epoxy or phenolic resin, carbon fiber, and composite, and
the embedded component comprises one or more of: an active component, a chip, a die, a passive component, embedded capacitors, deep trench capacitors, inductors, bridge die, voltage regulators, RF components, optical components, opto-electronic components, conductive interconnects, and vertical interconnect blocks (VIB);
forming a first patterned frontside conductive layer comprising at least one conductive trace, via, land, plane, line, and pad configured to be electrically coupled to the at least one embedded component over a front side of the substrate core;
disposing a first frontside layer of encapsulant or dielectric over the front side of the substrate core, the at least one embedded component, and the first patterned frontside conductive layer;
flipping the substrate core such that a back side of the substrate core is configured for processing;
forming a first patterned backside conductive layer comprising at least one conductive trace, via, land, plane, line, and pad over the back side of the substrate core, the first patterned frontside conductive layer configured to be electrically coupled to the at least one embedded component;
disposing a first backside layer of encapsulant or dielectric over the back side of the substrate core, over the at least one embedded component, and over the first patterned frontside conductive layer;
planarizing the first backside layer of encapsulant by grinding, chemical mechanical polishing (CMP), surface planarization, polishing, plasma etching, wet etching, or thinning by using a diamond-based cutter, to expose at least a portion of the first patterned backside conductive layer to form a first backside planar surface on the first backside layer of encapsulant;
forming a second patterned backside conductive layer over the first backside planar surface, the second patterned backside conductive layer configured to be electrically coupled to the first patterned frontside conductive layer;
disposing a second backside layer of encapsulant over the second patterned backside conductive layer and the first backside planar surface;
flipping the substrate core such that the first patterned frontside layer of encapsulant is configured for processing;
planarizing the first patterned frontside layer of encapsulant to expose at least a portion of the first patterned frontside conductive layer to form a first frontside planar surface on the first frontside layer of encapsulant;
forming a second patterned frontside conductive layer over the first frontside planar surface, the second patterned frontside conductive layer configured to be electrically coupled to the first patterned frontside conductive layer;
disposing a second frontside layer of encapsulant over the second patterned frontside conductive layer and the first frontside planar surface;
flipping the substrate core such that the second backside layer of encapsulant is configured for processing, and
planarizing the second backside layer of encapsulant to expose at least a portion of the second patterned backside conductive layer to form a second backside planar surface on the second backside layer of encapsulant.

2. The method of claim 1, wherein the substrate core comprises a mold compound formed by a molding process.

3. The method of claim 2, wherein at least one of the first frontside layer of encapsulant, the second frontside layer of encapsulant, the first backside layer of encapsulant and the second backside layer of encapsulant comprise mold compounds that are formed by a molding process, or comprise a build-up film applied by lamination.

4. The method of claim 1, wherein the tracking identifier comprises a 2-dimensional (2D) code comprising a data matrix, a laser mark, a witness mark, an ink mark, an inductor, an antenna, an RFID component, an accelerometer, or a directional component.

5. The method of claim 4, wherein the method further comprises:
providing the at least one tracking identifier as a first tracking identifier and a second tracking identifier;
reading the first tracking identifier, wherein the first tracking identifier is a 2D code, laser mark, witness mark, or the ink mark;
applying the second tracking identifier opposite the first tracking identifier; and
removing the first tracking identifier.

6. The method of claim 4, wherein the method further comprises reading the tracking identifier comprising the inductor, the antenna, the RFID component or the directional component.

7. The method of claim 1, wherein the encapsulant comprises a mold compound, a composite material, such as epoxy resin with filler, epoxy acrylate with filler, polytetrafluoroethylene, build-up film, or low k dielectrics.

8. A method of making an interconnect substrate, comprising:
providing a core, wherein the core comprises a composite core or molded core;
forming a first patterned frontside conductive layer over a front side of the core;
disposing a first frontside molded dielectric layer over the front side of the core and over the first patterned frontside conductive layer;
flipping the core such that a back side of the core is configured for processing; and
forming a first patterned frontside conductive layer over the back side of the core.

9. The method of claim 8 further comprising:
disposing a first backside dielectric layer over the back side of the composite core or molded core and over the first patterned frontside conductive layer;
planarizing the first backside molded dielectric layer to expose at least a portion of the first patterned backside conductive layer to form a first backside planar surface on the first backside dielectric layer;
forming a second patterned backside conductive layer over the first backside planar surface;
disposing a second backside dielectric layer over the second patterned backside conductive layer and the first backside planar surface;
flipping the composite core or molded core such that the first frontside dielectric layer is configured for processing; and
planarizing the first frontside dielectric layer to expose at least a portion of the first patterned frontside conductive layer to form a first frontside planar surface on the first frontside dielectric layer.

10. The method of claim 8, further comprising:
forming additional frontside and backside conductive layers interleaved with additional frontside and backside dielectric layers to form up to 30 layers of conductive frontside layers and conductive backside layers, and up to 30 layers of frontside and backside dielectric layers; and
counterbalancing stress and warpage by alternating the formation of the additional frontside and backside conductive layers and the additional frontside and backside dielectric layers.

11. The method of claim 9 further comprising forming the at least one frontside conductive layer or at least one backside conductive layer with unit specific patterning.

12. The method of claim 8 wherein at least one of the composite core or molded core and first frontside or first backside dielectric layers further comprises at least one tracking identifier comprising one or more of a 2-dimensional (2D) code, a laser mark, a witness mark, an ink mark, an inductor, an antenna, an RFID component, an accelerometer, or a directional component.

13. The method of claim 9, further comprising forming the composite core or molded core from at least one mold compound using a molding process, and forming at least one of the frontside and backside dielectric layers from an encapsulant or a laminated build-up film that performs well in a grinding operation.

14. The method of claim 12, wherein the method further comprises:
Forming the at least one tracking identifier as a first tracking identifier and a second tracking identifier;
reading the first tracking identifier, wherein the first tracking identifier is a 2D code, laser mark, witness mark, or ink mark;
applying a second tracking identifier opposite the first tracking identifier; and
removing the first tracking identifier.

15. The method of claim 12, wherein the method further comprises reading the tracking identifier comprising the inductor, the antenna, the RFID component or the directional component.

16. The method of claim 8, wherein:
the dielectric layer comprises a mold compound, a composite material, such as epoxy resin with filler, epoxy acrylate with filler, polytetrafluoroethylene, a build-up film, a dielectric, low k dielectrics; and
one or more other dielectric layers, comprising polyimide, may be disposed before, and under or in place of, the first frontside molded dielectric layer.

17. A method of making a molded interconnect substrate, the method comprising:
providing an unreinforced substrate core;
forming at least one vertical interconnect through a thickness of the unreinforced substrate core,
wherein the vertical interconnect comprises at least one of:
a conductive vertical interconnect;
a vertical interconnect block (VIB);
a vertical conductive contact;
a conductive stump;
a vertical connecting element, and
a via;
forming a first patterned frontside conductive layer comprising at least one conductive trace, via, land, plane, line, and pad over a front side of the unreinforced substrate core;
wherein the first patterned frontside conductive layer is coupled to the at least one vertical interconnect;
disposing a first frontside dielectric layer over the front side of the unreinforced substrate core and over the first patterned frontside conductive layer;
flipping the unreinforced substrate core such that a back side of the unreinforced substrate core is configured for processing;
forming a first patterned backside conductive layer comprising at least one conductive trace, via, land, plane, line, and pad over the back side of the unreinforced substrate core;
wherein the first patterned frontside conductive layer is coupled to the at least one vertical interconnect; and
disposing a first backside dielectric layer over the back side of the unreinforced substrate core and over the first patterned frontside conductive layer.

18. The method of making a molded interconnect substrate of claim 17 further comprising a tracking identifier comprising a 2-dimensional (2D) code comprising a data matrix, a laser mark, a witness mark, an ink mark, an inductor, an antenna, an RFID component, or a directional component.

19. The method of making a molded interconnect substrate of claim 18, wherein the method further comprises:
reading the tracking identifier comprising the 2D code, the laser mark, the witness mark, or the ink mark;
applying an additional tracking identifier opposite the tracking identifier; and
removing the tracking identifier by planarizing.

20. The method of making a molded interconnect substrate of claim 18, wherein the method further comprises reading the tracking identifier comprising the inductor, the antenna, the RFID component or the directional component.
